(19) United States
(12) Patent Application Publication
(10) Pub. No.: US 2026/0129799 A1
(43) Pub. Date: May 7, 2026

(54) THERMAL INTERFACE MATERIAL SYSTEMS, ASSEMBLIES FORMED THEREFROM, AND METHODS OF MANUFACTURE THEREOF

(71) Applicant: Arieca Inc., Pittsburgh, PA (US)

(72) Inventors: Hing Jii Mea, Pittsburgh, PA (US); Dylan S. Shah, Pittsburgh, PA (US); Keyton D. Feller, Pittsburgh, PA (US); Benjamin Dorau, Monroeville, PA (US); Cara Rossetti, Pittsburgh, PA (US); Peter Carter, Pittsburgh, PA (US); Loren Russell, Pittsburgh, PA (US); Navid Kazem, Pittsburgh, PA (US); Vivek Singh, Pittsburgh, PA (US)

(21) Appl. No.: 19/377,637

(22) Filed: Nov. 3, 2025

Related U.S. Application Data
(60) Provisional application No. 63/715,829, filed on Nov. 4, 2024.

(51) Int. Cl. H05K 7/20; C09J 5/06; C09J 7/22; C09K 5/10

(52) U.S. Cl. CPC H05K 7/2029; C09J 5/06; C09J 7/22; C09K 5/10; C09J 2203/326; C09J 2301/124; C09J 2301/41; C09J 2483/006

(57) ABSTRACT

Thermal interface materials systems, assemblies formed therefrom, and methods of manufacture thereof are provided. A system includes a thermal interface material (TIM) layer and a first adhesive layer disposed over the TIM layer. The TIM layer includes a first polymer component and liquid metal droplets dispersed through the first polymer component. The TIM layer exhibits a storage modulus of 10⁴ Pa to 10⁷ Pa.

### CROSS-REFERENCE

The present application claims priority to U.S. Provisional Application No. 63/715,829, filed Nov. 4, 2024. The entire contents of which is hereby incorporated by reference into this specification.

### GOVERNMENT SUPPORT

This Invention was made with U.S. Government support pursuant to a grant by Air Force Research Laboratory under agreement number FA8650-18-2-5402. The U.S. Government has certain rights in the Invention.

### FIELD

The present disclosure relates to thermal interface materials systems, assemblies formed therefrom, and methods of manufacture thereof.

### BACKGROUND

A thermal interface material (TIM) can be used to thermally connect two or more layers together. For example, TIMs are often used in CPU packages to thermally connect the integrated heat spreader (HS) of a CPU package to a heat sink. There are various types of TIMs that can be used. However, current TIMs present challenges.

### SUMMARY

Various aspects of the present disclosure are directed to a system comprising a thermal interface material (TIM) layer and a first adhesive layer disposed over the TIM layer. The TIM layer comprises a first polymer component and liquid metal droplets dispersed through the first polymer component. The TIM layer exhibits a storage modulus of 10⁴ Pa to 10⁷ Pa. In various examples, the liquid metal droplets comprise an aspect ratio of at least 1.1. In certain examples, a width of the liquid metal droplets are substantially aligned with a longitudinal plane of the TIM layer and/or a width of the liquid metal droplets are offset from a longitudinal plane of the TIM layer. In various examples, the first adhesive layer exhibits an adhesive strength in a range of 10³ to 10⁸ Pa or 10¹ to 10⁸ Pa. In various examples, the TIM layer further comprises at least one of a catalyst, rigid particles, deformable particles, a coupling agent, fumed silica, a conductive agent, an additive, and a surfactant. In certain examples, the TIM layer has an ultimate tensile strain of at least 30%. In various examples, the system can further comprise a second adhesive layer, a first temporary substrate, and/or a second temporary substrate.

Additional various aspects of the present disclosure are directed to an assembly comprising a first component layer, a second component layer and a system compressed and disposed in contact with and between the first component layer and the second component layer.

The system comprises a TIM layer and a first adhesive layer disposed over the TIM layer. The TIM layer comprises a first polymer component and liquid metal droplets dispersed through the first polymer component. The TIM layer exhibits a storage modulus of 10⁴ Pa to 10⁷ Pa. In various examples, the first component layer and the second component layer, individually, comprise at least one of a battery, a processor, a heat sink, an integrated heat spreader, a heat pipe, a case, a fan, a liquid cooler, a relay, a SiC power module, a GaN power module, a memory chip, an integrated circuit, an antenna and packaging. In certain examples, the first component layer, the second component layer, or a combination thereof, comprise a pretreated surface in contact with the system.

Additional certain aspects of the present disclosure are directed to a method of manufacturing an assembly. The method comprises applying a system in contact with and between a first component layer of and a second component layer. The method comprises compressing the system. The system comprises a TIM layer and a first adhesive layer disposed over the TIM layer. The TIM layer comprises a first polymer component and liquid metal droplets dispersed through the first polymer component. The TIM layer exhibits a storage modulus of 10⁴ Pa to 10⁷ Pa.

Additional various aspects of the present disclosure are directed to a method comprising applying a TIM composition to a temporary substrate at a first thickness, thereby forming a TIM layer. The TIM composition comprising a first polymer component and liquid metal droplets dispersed through the first polymer component and having a first aspect ratio. The method comprises applying a force to the TIM composition to deform the liquid metal droplets such that the liquid metal droplets have a second aspect ratio. The second aspect ratio is greater than the first aspect ratio. The method comprises curing the first polymer component, thereby forming a TIM layer having the first polymer component that is cured and the liquid metal droplets having the second aspect ratio. In various examples, the method can comprise removing the temporary substrate. In certain examples, applying a force to the TIM layer comprises applying a shear force to the TIM layer, and/or applying a normal force to the TIM layer to reduce the first thickness to a second thickness. In various examples, curing the first polymer component occurs during applying a force to the TIM layer, after applying a force to the TIM layer, or a combination thereof. In various examples, applying the TIM composition to the temporary substrate comprises dispensing, extruding, applying with a utensil, stencil printing, 3D printing, screen printing, spin coating, calendaring, film casting, slot-die coating, or a combination thereof.

Additional certain aspects of the present disclosure are directed to a method comprising applying a TIM composition to a temporary substrate at a first thickness, thereby forming a TIM layer. The TIM composition comprises a first polymer component and liquid metal droplets dispersed through the first polymer component and having a first aspect ratio. The method comprises applying a force to the TIM layer to deform the liquid metal droplets such that the liquid metal droplets have a second aspect ratio. The second aspect ratio is greater than the first aspect ratio. The method comprises curing the first polymer component, thereby forming a cured layer having the first polymer component that is cured and the liquid metal droplets having the second aspect ratio. The method comprises applying an adhesive layer to the TIM layer, the cured layer, or a combination thereof.

The present invention can provide both a low contact resistance at the material interfaces and a low thermal resistance through the TIM system. The low contact resistance can be enabled by the application of the TIM layer using an adhesive layer and a TIM layer that is elastomeric, so that the polymer and liquid metal droplets can adapt to the surface of the layer to achieve a desired contact resistance and the adhesive layer can maintain the contact. The low thermal resistance through the TIM layer can be enabled by the liquid metal droplets, including the size and/or shape of the liquid metal droplets. The use of a pre-cured TIM layer can lead to manufacturing efficiencies, reductions in cost, and/or improvements in the use of the TIM system, such as, for example, resistance to liquid metal coalescence and/or compatibility with pick and place robots. These and other benefits realizable from various embodiments of the present invention will be apparent from the description that follows.

### BRIEF DESCRIPTION OF THE DRAWINGS

The features and advantages of various examples of the present invention, and the manner of attaining them, will become more apparent, and the examples will be better understood by reference to the following description of examples taken in conjunction with the accompanying drawing, wherein:

FIG. 1 is a side view of a thermal interface material (TIM) system according to the present disclosure;

FIG. 2 is a side view of a TIM system prior to deformation of the liquid metal droplets;

FIG. 3 is a side view of the TIM system of FIG. 2 after deformation of the liquid metal droplets using a normal force and curing the TIM layer;

FIG. 4 is a side view of an assembly comprising the TIM system of FIG. 3;

FIG. 5 is a side view of a TIM system comprising adhesive layers after deformation of the liquid metal droplets using a normal force;

FIG. 6 is a side view of an assembly comprising the TIM system of FIG. 5;

FIG. 7 is a side view of the TIM system of FIG. 2 after deformation of the liquid metal droplets using a shear force and curing the TIM layer;

FIG. 8 is a side view of an assembly comprising the TIM system of FIG. 7;

FIG. 9 is a side view of a TIM system comprising adhesive layers after deformation of the liquid metal droplets using a shear force; and

FIG. 10 is a side view of an assembly comprising the TIM system of FIG. 9.

Corresponding reference characters indicate corresponding parts throughout the several views. The exemplifications set out herein illustrate certain examples, in one form, and such exemplifications are not to be construed as limiting the scope of the examples in any manner.

### DETAILED DESCRIPTION

Certain exemplary aspects of the present invention will now be described to provide an overall understanding of the principles of the composition, function, manufacture, and use of the compositions and methods disclosed herein. An example or examples of these aspects are illustrated in the accompanying drawing. Those of ordinary skill in the art will understand that the compositions, articles, and methods specifically described herein and illustrated in the accompanying drawing are non-limiting exemplary aspects and that the scope of the various examples of the present invention is defined solely by the claims. The features illustrated or described in connection with one exemplary aspect may be combined with the features of other aspects. Such modifications and variations are intended to be included within the scope of the present invention.

Pressure values as used herein refer to gauge pressure unless stated otherwise.

Properly formulating a thermal interface material (TIM) that is applied to a circuit assembly between an integrated heat spreader (IHS) and a heat sink can require balancing the thermal resistance through the TIM and the contact resistance at the material interfaces. For example, an uncured polymeric material may have a low contact resistance at the material interfaces but a high thermal resistance through the material. A solid metal may have a low thermal resistance through the material but a high contact resistance at the material interfaces. There are challenges with balancing contact resistance, thermal resistance, and manufacturability of TIM materials.

Thus, the present disclosure provides, in various examples, thermal interface materials systems, assemblies formed therefrom, and methods of manufacture that can be capable to enhance balancing contact resistance, thermal resistance, and manufacturability. The TIM system can comprise a TIM layer comprising a polymer component and liquid metal droplets dispersed through the polymer component. The TIM layer exhibits a storage modulus of 10⁴ Pa to 10⁷ Pa. The TIM system can optionally comprise an adhesive layer disposed over the TIM layer.

As used in this specification, particularly in connection with layers, films, or materials, the terms “on,” “onto,” “over,” and variants thereof (e.g., “applied on,” “formed on,” “deposited on,” “provided on,” “located on,” and the like) mean applied, formed, deposited, provided, or otherwise located over a surface of a substrate but not necessarily in contact with the surface of the substrate. For example, a TIM “deposited on” a substrate or “deposited between” two elements does not preclude the presence of another layer or other layers of the same or different composition located between the applied TIM and the substrate or layers. Likewise, a second layer “deposited on” a first layer does not preclude the presence of another layer or other layers of the same or different composition located between the deposited second layer and the deposited TIM.

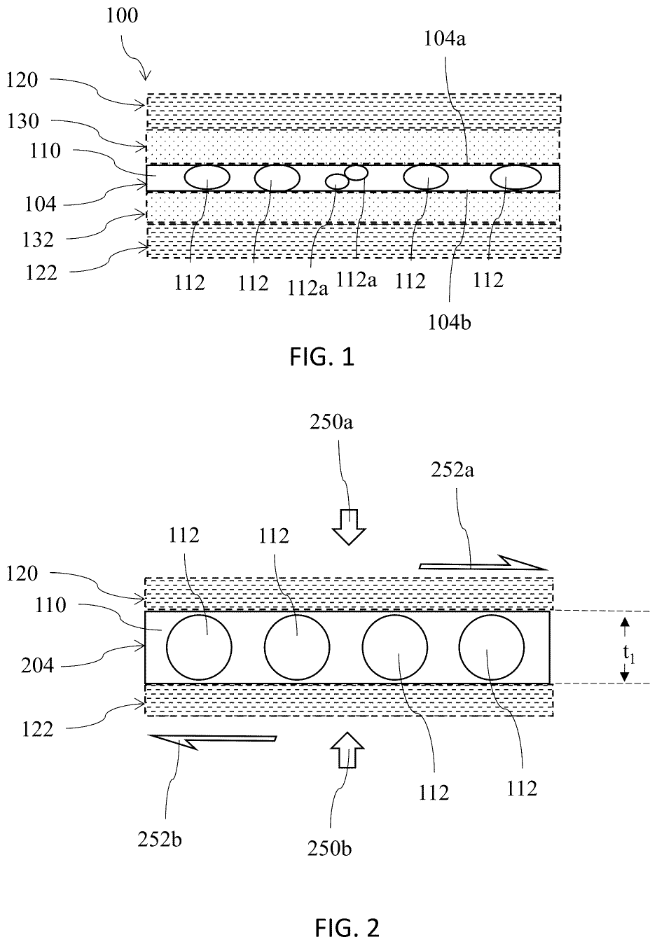

Referring to FIG. 1, a thermal interface material (TIM) system 100 is provided. The system 100 comprises a TIM layer 104 capable for thermal transfer, compliance, and/or enhancing manufacturability of an assembly comprising the system 100. The system 100 can comprise various other optional layers, such as, for example, an adhesive layer 130, an adhesive layer 132, a temporary substrate 120, a temporary substrate 122, or a combination thereof.

The adhesive layer 130 can be disposed over a first side 104a of the TIM layer 104 and the adhesive layer 132 can be disposed over a second side 104b of the TIM layer 104 such that the TIM layer 104 can be positioned intermediate the adhesive layer 130 and the adhesive layer 132. The first side 104a can be oppositely disposed from the second side 104b. In various examples, the adhesive layer 130 can be in contact with the first side 104a and the adhesive layer 132 can be in contact with the second side 104b. The adhesive layers 130 and 132 can enhance contact resistance and/or adhesion between the system 100 and other surfaces, while enabling a storage modulus of the TIM layer 104 to be desirable for manufacturability.

The temporary substrate 120 can be disposed over a first side 104a of the TIM layer 104 and the temporary substrate 122 can be disposed over a second side 104b of the TIM layer 104 such that the TIM layer 104 can be positioned intermediate the temporary substrate 120 and the temporary substrate 122. The adhesive layer 130 can be positioned intermediate the TIM layer 104 and the temporary substrate 120. The adhesive layer 132 can be positioned intermediate the TIM layer 104 and the temporary substrate 122. In various examples, the adhesive layer 130 can be in contact with the temporary substrate 120 and the adhesive layer 132 can be in contact with the temporary substrate 122. The temporary substrates 120 and 122 can enhance manufacturability of the system 100 and/or enable handling of the system 100 during manufacture of an assembly.

The composition for each layer in the system 100 can be configured based on the desired contact resistance, thermal resistance, manufacturability, and/or other properties of the system 100 desired. For example, the TIM layer 104 can comprise a polymer component, liquid metal droplets, and optional components. The TIM layer 104 can be formed from curing a TIM composition comprising a polymer component, liquid metal droplets, and optional components. The method for manufacturing the TIM layer 104 is discussed in more detail below with reference to FIG. 2.

As used in this specification, the terms “polymer” and “polymeric” means prepolymers, oligomers, and both homopolymers and copolymers. As used in this specification, “prepolymer” means a polymer precursor capable of further reactions or polymerization by a reactive group or reactive groups to form a higher molecular mass and/or cross-linked state.

The polymer component can comprise a polymeric binder, a thermosetting polymer, and/or a thermoplastic polymer. As used herein, the term “thermosetting” refers to polymers that “set” irreversibly upon curing or cross-linking, where the polymer chains of the polymeric components are joined together by covalent bonds, which is often induced, for example, by heat or radiation. In various examples, curing or a cross-linking reaction can be carried out under ambient conditions. Once cured or cross-linked, a thermosetting polymer may not flow upon the application of heat, may otherwise irreversibly increase in viscosity, and/or can be insoluble in conventional solvents. As used herein, the term “thermoplastic” refers to polymers that include polymeric components in which the constituent polymer chains are not joined (e.g., crosslinked) by covalent bonds and thereby can undergo liquid flow upon heating and are soluble in conventional solvents. In certain embodiments, the polymer can be elastomeric (e.g., rubbery, soft, stretchy), or rigid (e.g., glassy) For example, the polymer component can be elastomeric and may have an ultimate tensile strain of at least 30%, such as, for example at least 50%, at least 100%, at least 200%, or at least 300%. In various examples, TIM layer comprising the polymer component can be elastomeric and may have an ultimate tensile strain of at least 30%, such as, for example at least 50%, at least 100%, at least 200%, or at least 300%. Ultimate tensile strain can be measured according to ASTM D3039.

Thermosetting polymers may include at least one of a cross-linking agent that may comprise, for example, aminoplasts, polyisocyanates (including blocked isocyanates), polyepoxides, beta-hydroxyalkylamides, polyacids, anhydrides, organometallic acid-functional materials, polyamines, polyvinyls, polysilicon hydrides, polyalcohols, polyacid chlorides, polyhalides, and polyamides. A polymer may have functional groups that are reactive with the cross-linking agent.

The polymer component in the TIM layer described herein may be selected from any of a variety of polymers well known in the art. For example, the thermosetting polymer may comprise at least one of an acrylic polymer (e.g., an acrylate polymer), a vinyl polymer, a polyester polymer, a polyurethane polymer, polybutadiene, a polyamide polymer, a polyether polymer, a polysiloxane polymer (e.g., poly(dimethylsiloxone)), a silicon hydride polymer, a fluoropolymer, a polyisoprene polymer (e.g., rubber), and a copolymer of two or more thereof. The functional groups on a thermosetting polymer may be selected from any of a variety of reactive functional groups, including, for example, at least one of a carboxylic acid group, an amine group, an epoxide group, a hydroxyl group, a thiol group, a carbamate group, an amide group, a urea group, an isocyanate group (including a blocked isocyanate group), a vinyl group, a silicon hydride group, an acid chloride group, an acrylate group, a halide group, and a mercaptan group.

The thermoplastic polymer can comprise at least one of propylene-ethylene co-polymer, styrene-butadiene-styrene, polyether, and styrene ethylene butylene styrene. The polymer can comprise a melting point of at least 100 degrees Celsius, such as, for example, at least 120 degrees Celsius, at least 150 degrees Celsius, or at least 200 degrees Celsius.

The polymeric binder can be a polyether binder, a polyether modified binder (e.g., an ethoxylate of an alcohol, a propoxylate of an alcohol), a carboxylic acid, an amine, a phenol, a sorbitan, a sorbitan ester, or a combination thereof.

The polymer component can optionally comprise other components such as, for example, fumed silica, a coupling agent, and an additive.

In various examples, the polymer component can comprise 0.1% by weight to 0.5% by weight of a coupling agent, if present, based on a total weight of the polymer component. For example, the coupling agent can comprise at least one of 3-Glycidoxypropyltrimethoxysilane, 3-Glycidoxypropyltriethoxysilane, 3-Aminopropyltrimethoxysilane, and Bis(3-trimethoxysilylpropyl)amine. The coupling agent can promote adhesion to substrates.

In certain examples, the polymer component can comprise 0.1% by weight to 5% by weight of a fumed silica, if present, based on a total weight of the polymer component.

In various examples, the polymer component can comprise 0.1% by weight to 40% by weight of an additive, if present, based on a total weight of the polymer component. The additive can be used to adjust mechanical and/or chemical properties of the polymer component and/or resulting TIM layer. The additive can comprise a diluent, a plasticizer, or a combination thereof. In various examples, the additive can comprise an ethylene glycol oligomer, a propylene glycol oligomer, a diethylene glycol, a dipropylene glycol, a diethylene glycol mono-alkyl ether, a diethlyene glycol di-alkyl ether, a dipropylene glycol mono-alkyl ether, a dipropylene glycol di-alkyl ether, a triethylene glycol, tripropylene glycol, a triethylene glycol mono-alkyl ether, a triethlyene glycol di-alkyl ether, a tripropylene glycol mono-alkyl ether, a tripropylene glycol di-alkyl ether, or a combination thereof.

The additive can be used to configure the viscosity of the polymer component, configure the compliance of the polymer component, and/or adjust a concentration of a component in the polymer component to enhance stability. For example, the amount of shear imparted to the TIM composition during mixing can affect the formation of the liquid metal droplets. It is believed, that the viscosity of the polymer component, among other factors, can contribute to the amount of shear that can be imparted to the TIM composition. Thus, by configuring the TIM composition with a desirable viscosity, the amount of shear imparted during mixing of the TIM composition can be adjusted.

The TIM composition can comprise at least 5% polymer component by total volume of the TIM, such as, for example, at least 7% polymer component, at least 10% polymer component, at least 15% polymer component, at least 20% polymer component, at least 25% polymer component, at least 30% polymer component, at least 40% polymer component, at least 50% polymer component, or at least 60% polymer component, all based on the total volume of the TIM composition. The TIM composition can comprise no greater than 80% polymer component by total volume of the TIM composition, such as, for example, no greater than 70% polymer component, no greater than 60% polymer component, no greater than 50% polymer component, no greater than 40% polymer component, no greater than 30% polymer component, no greater than 25% polymer component, no greater than 20% polymer component, no greater than 15% polymer component, or no greater than 10% polymer component, all based on the total volume of the TIM composition. The TIM composition can comprise a range of 5% to 80% polymer component by total volume of the TIM composition, such as, for example, 5% to 70% polymer component, 5% to 60% polymer component, 5% to 50% polymer component, 5% to 40% polymer component, 5% to 30% polymer component, 7% to 30% polymer component, 10% to 30% polymer component, 5% to 25% polymer component, 5% to 20% polymer component, or 5% to 10% polymer component, all based on the total volume of the TIM composition. The amount of the polymer component can be selected while balancing a desired elasticity, adhesiveness, and a desired effective thermal conductivity of the TIM composition.

The liquid metal droplets are dispersed throughout the polymer component. The TIM composition can comprise at least 20% liquid metal droplets by total volume of the TIM composition, such as, for example, at least 25% liquid metal droplets, at least 30% liquid metal droplets, at least 40% liquid metal droplets, at least 50% liquid metal droplets, at least 60% liquid metal droplets, at least 70% liquid metal droplets, at least 80% liquid metal droplets, or at least 90% liquid metal droplets, all based on the total volume of the TIM composition. The TIM composition can comprise no greater than 95% liquid metal droplets by total volume of the TIM composition, such as, for example, no greater than 93% liquid metal droplets, no greater than 90% liquid metal droplets, no greater than 80% liquid metal droplets, no greater than 70% liquid metal droplets, no greater than 60% liquid metal droplets, no greater than 50% liquid metal droplets, no greater than 40% liquid metal droplets, or no greater than 30% liquid metal droplets, all based on the total volume of the TIM composition. The TIM composition can comprise a range of 20% to 95% liquid metal droplets by total volume of the TIM composition, such as, for example, 30% to 95% liquid metal droplets, 40% to 95% liquid metal droplets, 50% to 95% liquid metal droplets, 50% to 93% liquid metal droplets, 60% to 93% liquid metal droplets, 70% to 95% liquid metal droplets, or 70% to 93% liquid metal droplets, all based on the total volume of the TIM composition. The amount of liquid metal droplets can be selected while balancing a desired elasticity and a desired effective thermal conductivity of the TIM composition.

The liquid metal droplets are dispersed throughout the polymer component and the liquid metal droplets can be emulsified therein. The liquid metal droplets for the TIM composition can comprise at least one of gallium, a gallium alloy, indium, an indium alloy, tin, a tin alloy, mercury, and a mercury alloy. The liquid metal droplets can comprise a melting point of no greater than 30 degrees Celsius, such as, for example, no greater than 25 degrees Celsius, no greater than 20 degrees Celsius, no greater than 15 degrees Celsius, no greater than 10 degrees Celsius, no greater than 5 degrees Celsius, no greater than 0 degrees Celsius, or no greater than −10 degrees Celsius. The liquid metal droplets can comprise a melting point of at least −40 degrees Celsius, such as, for example, at least −20 degrees Celsius, at least −19 degrees Celsius, at least −10 degrees Celsius, at least 0 degrees Celsius, at least 5 degrees Celsius, at least 10 degrees Celsius, at least 15 degrees Celsius, at least 20 degrees Celsius, or at least 25 degrees Celsius. The liquid metal droplets can comprise a melting point in a range of −40 degrees Celsius to 30 degrees Celsius, such as, for example, −20 degrees Celsius to 30 degrees Celsius, −19 degrees Celsius to 30 degrees Celsius, or −19 degrees Celsius to 25 degrees Celsius. The determination of the melting point can be made at a pressure of 1 atmosphere absolute. In certain embodiments, the TIM composition can comprise Gallium Indium Tin (Galinstan) and a melting point of −19 degrees Celsius.

The composition and/or mixing techniques can be selected to achieve a desired D₅₀ and/or D₉₀ of the liquid metal droplets in the TIM composition prior to deformation. The D₅₀ of the liquid metal droplets can be at least 1 micron prior to deformation, such as, for example, at least 5 microns, at least 10 microns, at least 15 microns, at least 20 microns, at least 30 microns, at least 35 microns, at least 40 microns, at least 50 microns, at least 60 microns, at least 70 microns, at least 80 microns, at least 90 microns, at least 100 microns, at least 120 microns, at least 150 microns, or at least 200 microns, all prior to deformation. The D₅₀ of the liquid metal droplets can be no greater than 300 micron, such as, for example, no greater than 250 microns, no greater than 200 microns, no greater than 150 microns, no greater than 120 microns, no greater than 100 microns, no greater than 90 microns, no greater than 80 microns, no greater than 70 microns, no greater than 60 microns, no greater than 50 microns, no greater than 40 microns, no greater than 35 microns, no greater than 30 microns, no greater than 20 microns, no greater than 10 microns, or no greater than 5 microns, all prior to deformation. For example, the D₅₀ of the liquid metal droplets can be in a range of 1 microns to 300 microns, such as, for example, 5 microns to 300 microns, 150 microns to 250 microns, 5 microns to 150 microns, 15 to 150 microns, 35 microns to 150 microns, 35 microns to 70 microns, or 5 microns to 100 microns, all measured prior to deformation.

As used herein, Dₓ can be measured using microscopy (e.g., optical microscopy or electron microscopy). The size can be the diameter of spherical particles or the width along the largest dimension of ellipsoidal or otherwise irregularly shaped particles. As used herein, “D_{X}” of particles refers to the diameter at which X % of the particles have a smaller diameter.

The D₉₀ of the liquid metal droplets can be at least 1 micron, such as, for example, at least 5 microns, at least 10 microns, at least 15 microns, at least 20 microns, at least 30 microns, at least 35 microns, at least 40 microns, at least 50 microns, at least 60 microns, at least 70 microns, at least 80 microns, at least 90 microns, at least 100 microns, at least 120 microns, at least 150 microns, or at least 200 microns, all prior to deformation. The D₉₀ of the liquid metal droplets can be no greater than 300 micron, such as, for example, no greater than 250 microns, no greater than 200 microns, no greater than 150 microns, no greater than 120 microns, no greater than 100 microns, no greater than 90 microns, no greater than 80 microns, no greater than 70 microns, or no greater than 50 microns, all prior to deformation. For example, the D₉₀ of the liquid metal droplets can be in a range of 1 microns to 300 microns, such as, for example, 5 microns to 300 microns, 150 microns to 250 microns, 10 microns to 200 microns, 15 to 150 microns, 35 microns to 150 microns, 35 microns to 120 microns, or 50 microns to 100 microns, all measured prior to deformation.

The TIM composition can optionally comprise other components such as, for example, a catalyst, rigid particles, deformable particles, a coupling agent, fumed silica, a conductive agent (e.g., graphene, graphite, CNTs, metallic (nano)wire), an additive, and a surfactant. The rigid spacer particles can comprise at least one of a metal or metal alloy (e.g., iron, an iron alloy (e.g., steel), vanadium, a vanadium alloy, niobium, a niobium alloy, titanium, a titanium alloy, copper, a copper alloy (e.g., bronze)), a rigid polymer, a glass and a ceramic. The rigid spacer particles can be resistant to deformation and/or corrosion by the liquid metal droplets. For example, the rigid spacer particles can comprise a Young's modulus of at least 100 MPa (megapascals), such as, for example, at least 110 MPa, at least 150 MPa, at least 200 MPa, at least 250 MPa, at least 500 MPa, at least 750 MPa, at least 1 GPa (gigapascals), or at least 2 GPa. Young's Modulus can be measured according to ASTM E111-17. The TIM can comprise a range of 0.1% to 25% rigid spacer particles by total volume of the TIM, such as, for example, 0.1% to 4% rigid spacer particles, 0.1% to 3% rigid spacer particles, 1% to 4% rigid spacer particles, or 1% to 3% rigid spacer particles, all based on the total volume of the TIM.

The D₉₀ and/or D₅₀ of the rigid spacer particles in the TIM composition can be selected to achieve a desired thickness in the system 100 and/or assembly created therefrom. For example, the D₉₀ of the rigid spacer particles can be at least 1 micron, such as, for example, at least 5 microns, at least 10 microns, at least 20 microns, at least 30 microns, at least 35 microns, at least 40 microns, at least 50 microns, at least 60 microns, at least 70 microns, at least 80 microns, at least 90 microns, at least 100 microns, at least 120 microns, at least 200 microns, or at least 300 microns. The D₉₀ of the rigid spacer particles can be no greater than 350 microns, such as, for example, no greater than 300 microns, no greater than 200 microns, no greater than 125 microns, no greater than 120 microns, no greater than 100 microns, no greater than 90 microns, no greater than 80 microns, no greater than 70 microns, no greater than 60 microns, no greater than 50 microns, no greater than 40 microns, no greater than 35 microns, no greater than 30 microns, no greater than 20 microns, no greater than 10 microns, or no greater than 5 microns. For example, the D₉₀ of the rigid spacer particles can be in a range of 1 microns to 350 microns, such as, for example, 10 microns to 200 microns, 15 microns to 150 microns, 5 microns to 125 microns, 35 microns to 125 microns, 35 microns to 70 microns, or 50 microns to 70 microns.

The TIM composition can be manufactured by mixing a polymer component and bulk liquid metal together, thereby forming liquid metal droplets from the liquid metal and dispersing the liquid metal droplets throughout the second polymer component to create a mixture. The mixture can be an emulsion (e.g., liquid dispersed phase in liquid continuous phase). The polymer component and bulk liquid metal can be mixed together with at least one of stirring, a high shear mixer, low-shear mixing, a centrifugal mixer, by shaking in a container, a mortar and pestle, and sonication to form an emulsion or dispersion, as the case may be. More details about exemplary ways to form an emulsion of the second polymer component and the liquid metal droplets are described in (1) published PCT WO/2019/136252, entitled “Method of Synthesizing a Thermally Conductive and Stretchable Polymer Composite”, (2) published U.S. application US 2017/0218167, entitled “Polymer Composite with Liquid Phase Metal Inclusions,” (3) U.S. Pat. No. 10,777,483, entitled “Method, apparatus, and assembly for thermally connecting layers”, (4) U.S. Provisional Patent No. 63/268,134, entitled “Thermal interface material, an integrated circuit assembly, and a method for thermally connecting layers”, (5) published PCT WO 2022/204689 entitled “A method, apparatus, and assembly for thermally connecting layers with thermal interface materials comprising rigid particles”, and (6) U.S. provisional application 63/479,879, entitled “A method of Manufacture of a Thermal Interface Material, a Thermal Interface Material Formed Therefrom, and an Integrated Circuit Formed Therefrom”, all of which are incorporated herein by reference in their entirety.

The polymer component, liquid metal, and optional other optional components can be added in quantities to achieve a desired composition of the TIM as described above.

The other optional components such as, for example, a catalyst, rigid particles, deformable particles, a coupling agent, fumed silica, a conductive agent, an additive, an additive, and a surfactant can be added to the polymer component prior to forming the TIM composition, during the formation of the TIM composition, and/or after forming the TIM composition, as the application may require.

The composition and/or mixing techniques can be chosen such that the viscosity of the TIM composition is less than 2,000,000 cP (centipoise), such as, for example, less than 750,000 cP, less than 500,000 cp, less than 250,000 cP, 200,000 cP, less than 150,000 cP, less than 100,000 cP, less than 50,000 cP, less than 15,000 cP, less than 14,000 cP, less than 13,000 cP, less than 12,000 cP, less than 11,000 cP, or less than 10,000 cP. For example, the composition and/or mixing techniques can be chosen such that the viscosity of the TIM composition is at least 1,000 cP, such as, for example, at least 2,000 cP, at least 5,000 cP, or at least 10,000 cP. The composition and/or mixing techniques can be chosen such that the viscosity of the TIM composition is in a range of 1,000 cP to 2,000,000 cP, such as, for example, 2,000 cP to 750,000 cP, or 2,000 cP to 500,000 cP. The viscosity of the TIM composition can be measured by a parallel plate (40 mm) rheometer at 25 degrees Celsius, a frequency of 10 radians per second, and a strain of 5%. Selecting the viscosity can require a balance of installation pressure, which may increase with a high viscosity, an ability to resist undesirably fast spreading during application of the TIM and pump out during operation, and viscosity of the polymer component.

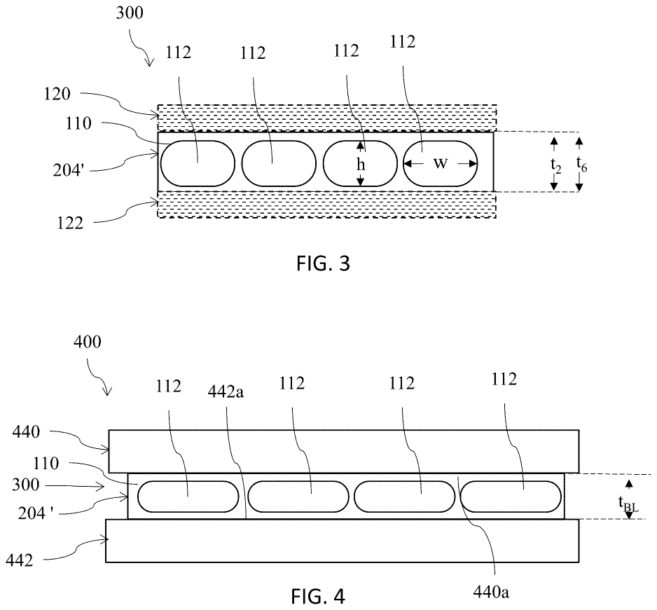

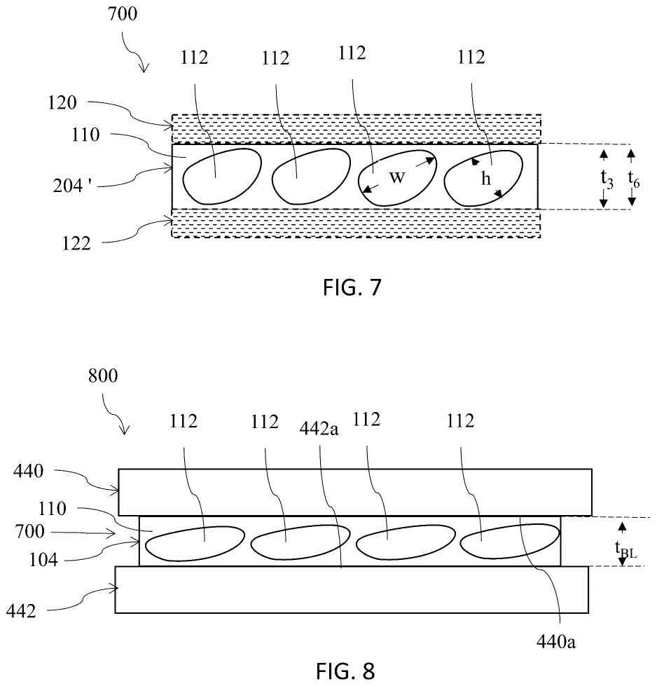

Referring to FIG. 2, the TIM composition 204 can be used to form a TIM layer 204′ illustrated in FIGS. 3 and 7. For example, referring back to FIG. 2, the TIM composition 204 can be applied (e.g., deposited) at a first thickness, t₁ on a temporary substrate 122 by, for example, at least one of dispensing (e.g., auger or air controlled), extruding (e.g., through a nozzle, such as, a circular nozzle, a fan nozzle, slit nozzle, or other nozzle shape), applying with a utensil (e.g., brush, spatula), stencil printing, 3D printing, screen printing, spin coating, calendaring, film casting, slot-die coating, or a combination thereof. The TIM composition 204 can be deposited in a conformable state such that the TIM composition 204 can adapt to the surfaces of the temporary substrate 122 to achieve a desired level of surface contact therebetween and shape.

In various examples, the TIM composition 204 can be applied directly to the temporary substrate 122 and, thereafter, the temporary substrate 120 can be applied directly to the TIM composition 204. In various other examples, the TIM composition 204 can be applied directly to the temporary substrate 120 and, thereafter, the temporary substrate 122 can be applied directly to the TIM composition 204. In certain examples, the TIM composition 204 can be applied to both the temporary substrate 120 and the temporary substrate 122 and then the temporary substrate 120 and the temporary substrate 122 can be applied together. In various examples, after deposition of the TIM composition 204 and deformation of the liquid metal droplets 112, the TIM composition 204 can be in direct contact with and between the temporary substrates 120 and 122, or an adhesive layer may be intermediate the TIM composition 204 and the temporary substrate 120 or temporary substrate 122.

Referring to FIG. 2 again, the TIM composition 204 can be dispensed from a container and applied to a layer in a conformable state. The TIM composition 204 can be stored in a container prior to use. The TIM composition 204 can be in a conformable state in the container. The container can comprise at least one of a pillow pack, a syringe, a beaker, ajar, a bottle, and a drum. In various examples, the container can be a ready to use dispensing device, such as, for example, a pillow pack or a syringe. In certain examples, the TIM composition 204 may not be stored and can be used after creation of the emulsion without storage.

The first thickness, t₁, can be selected to enhance the effective thermal conductivity of the system 100 and/or spatial uniformity of the liquid metal droplets 112 packing within the TIM composition 204 and a TIM layer formed therefrom. The first thickness, t₁, can be at least 1 times a D₉₀ of the liquid metal droplets 112 prior to deformation, such as, for example, at least 1.1 times, at least 1.25 times, at least 2.5 times, at least 3 times, at least 3.3 times, at least 4 times, at least 5 times, at least 6 times, at least 10 times, at least 20 times, at least 50 times, or at least 100 times, all of a D₉₀ of the liquid metal droplets 112 prior to deformation. The first thickness, t₁, can be no greater than 1,000 times a D₉₀ of the liquid metal droplets 112, such as, for example, no greater than 500 times, no greater than 250 times, no greater than 150 times, no greater than 100 times, no greater than 50 times, no greater than 15 times, no greater than 10 times, no greater than 6 times, no greater than 5 times, no greater than 3.3 times, no greater than 2.5 times, no greater than 1.25 times, or no greater than 1.1 times, all of a D₉₀ of the liquid metal droplets 112 prior to deformation. The first thickness, t₁, can be in a range of 1 times to 1,000 times a D₉₀ of the liquid metal droplets 112 prior to deformation, such as, for example, 1.1 times to 1,000 times, 2 times to 500 times, 2 times, to 150 times, 2 times to 100 times, 2 times to 50 times, 2 times to 10 times, 3 times to 10 times, 3 times to 6 times, 1 time to 1.25 times, 1.25 times to 3.3 times, 3.3 times to 10 times, 10 times to 100 times, or 100 times to 1,000 times, all of a D₉₀ of the liquid metal droplets 112 prior to deformation. Because the first thickness, t₁, can be at least 1.1 times the D₉₀ of the liquid metal droplets 112 prior to deformation, a desired distribution of the liquid metal droplets in the TIM composition 204 and spatial uniformity of the liquid metal droplets 112 packing within the TIM composition 204 can be achieved, thereby enhancing the effective thermal conductivity of the TIM composition 204 and a TIM layer formed therefrom. For example, the first thickness, t₁, can be in a range of 30 microns to 4,000 microns, such as, for example, 30 microns to 500 microns.

In certain non-limiting embodiments, one of liquid metal droplet 112 may span the first thickness, t₁. For example, the D₉₀ of the liquid metal droplets 112 may be substantially equal to the first thickness, t₁.

The temporary substrate 120 and/or 122 can be a film, a tray, a plate, and/or other surface. For example, the temporary substrate can comprise polyethylene terephthalate (PET), paper, steel, polytetrafluoroethylene, PTFE, polyethylene (PE), polypropylene (PP), silicone, a flouropolymer, cellulose, polyvinyl chloride, polyvinyl acetate, wax-impregnated paper, or a combination thereof.

After application of the TIM composition 204, a force can be applied to the TIM composition 204 to deform the liquid metal droplets 112. For example, a temporary substrate 120 can be disposed over the TIM composition 204, and the temporary substrate 120 and/or temporary substrate 122 can be moved relative to the other to apply a force to the TIM composition. The force applied can be a normal force, which can be applied by urging the temporary substrates 120 and 122 together in the directions 250a and 250b, respectively resulting in system 300 in FIG. 3.

In various examples, the force applied can be a shear force, which can be applied by urging the temporary substrates 120 and 122 in the directions 252a and 252b, respectively, or urging the temporary substrates 120 and 122 in the directions 252b and 252a, respectively resulting in system 700 in FIG. 7. A shear force can be produced during dispensing and/or after dispensing of the TIM composition 204. For example, using stenciling and/or a slit coater can create a shear force on the TIM composition 204 during dispensing. In certain examples, the force applied can be a combination of a normal force and a shear force.

The force applied to the TIM composition 204 can be at least 3 kPa, such as, for example, at least 10 kPa, at least 70 kPa, at least 100 kPa, or at least 300 kPa. The force applied to the TIM composition 204 can be no greater than 2,000 kPa, such as, for example, no greater than 1,000 kPa, no greater than 600 kPa, no greater than 500 kPa, no greater than 350 kPa, or no greater than 100 kPa. For example, the force applied to the TIM composition can be in a range of 3 kPa to 2,000 kPA, such as, for example, 3 kPa to 1,000 kPa, 3 kPa to 600 kPa, 3 kPa to 500 kPa, 3 kPa to 350 kPa, 3 kPa to 100 kPa.

Applying a force to the TIM composition 204 can deform the liquid metal droplets 112 dispersed within the polymer component 110 of the TIM composition 204. Because the polymer component 110 is still liquid and conformable and moveable, the force can deform the liquid metal droplets 112. The liquid metal droplets 112 can be in the liquid phase during deformation, such that a lower pressure is required for the compression and a desired deformation can be achieved.

In various examples, the liquid metal droplets 112 prior to application of the force can have a first average aspect ratio and after deformation the liquid metal droplets 112 can have a second average aspect ratio. The second average aspect ratio can be different than the first average aspect ratio. For example, the second average aspect ratio can be greater than the first average aspect ratio. The average aspect ratio can be a mean ratio of the width to the height of the liquid metal droplets 112. In various examples, the first aspect ratio can be 1 and the second aspect ratio can be greater than 1. In certain examples, the first aspect ratio can be in a range of 1 to 1.5. In certain examples, the second aspect ratio can be at least 0.5 greater than the first aspect ratio, such as, for example, at least 1 greater than the first aspect ratio, at least 2 greater than the first aspect ratio, or at least 5 greater than the first aspect ratio. In certain examples, the second aspect ratio can be at least 2 after deformation, such as, for example, at least 3, or at least 4 after deformation. In various examples, the liquid metal droplets can be substantially spherical prior to deformation and ellipsoidal after deformation.

Referring back to FIG. 2, the application of the force to the TIM composition 204 can comprise applying a normal force in the directions 250a and 250b to reduce the first thickness, t₁, to a second thickness, t₂ as shown in FIG. 3. In various examples, the second thickness, t₂, can be less than the first thickness, t₁.

The resulting liquid metal droplets can comprise a width, w, substantially aligned with a longitudinal plane defined by the TIM layer 204′. The height, h, of the liquid metal droplets 112 can be substantially aligned with a thickness of the TIM composition 204 (e.g., second thickness, t₂). The width, w, of the liquid metal droplets 112 can increase upon compression of the TIM composition 204. For example, in certain examples, the diameter of liquid metal droplets 112 prior to compressing can be 200 m (with a first aspect ratio of 1) and after compression to a thickness of 100 m, the liquid metal droplets 112 can be deformed to an ellipsoidal shape with a 400 μm width (e.g., second aspect ratio of 4).

Referring back to FIG. 2, the application of the force to the TIM composition 204 can comprise applying a shear force in the directions 252a and 252b such that a width, w, of the liquid metal droplets 112 are offset from a longitudinal plane defined by the TIM composition 204 as shown in FIG. 7. In various examples, the third thickness, t₃, can be substantially the same as the first thickness, t₁. In certain examples, the third thickness, t₃, can be less than the first thickness, t₁.

The resulting liquid metal droplets 112 can comprise a height, h, offset from the thickness of the TIM composition 204 (e.g., the third thickness, t₃). For example, the width, w, may be offset from the longitudinal plane and the height, h, of the liquid metal droplets 112 may be offset from the thickness of the TIM composition 204. The width of the liquid metal droplets 112 can increase upon application of the shear force to the TIM composition 204.

The second thickness, t₂, and/or third thickness, t₃, can be no greater than 1990 microns, such as, for example, no greater than 1,900 microns, no greater than 1,500 microns, no greater than 1,000 microns, no greater than 500 microns, no greater than 250 microns, no greater than 200 microns, no greater than 150 microns, no greater than 145 microns, no greater than 140 microns, no greater than 125 microns, no greater than 100 microns, no greater than 80 microns, no greater than 70 microns, no greater than 50 microns, no greater than 40 microns, no greater than 35 microns, or no greater than 30 microns. The second thickness, t₂, and/or third thickness, t₃, can be at least 30 microns, such as, for example, at least 35 microns, at least 40 microns, at least 50 microns, at least 70 microns, at least 75 microns, at least 80 microns, at least 100 microns, at least 120 microns, at least 140 microns, at least 145 microns, at least 200 microns, at least 500 microns, or at least 1000 microns. The second thickness, t₂, and/or third thickness, t₃, can be in a range of 1 micron to 1990 microns, such as, for example, 30 microns to 1990 microns, 30 micron to 1,000 microns, 30 microns to 500 microns, 30 microns to 250 microns, 30 microns to 300 microns, 30 microns to 250 microns, 30 micron to 200 microns, 30 microns to 150 microns, 50 microns to 120 microns, or 75 microns to 125 microns.

In certain examples, the liquid metal droplets 112 can be aligned substantially in a monolayer as shown in FIGS. 3 and 5 after deformation. The monolayer can be achieved by selecting the D₅₀ and/or D₉₀ of the liquid metal droplets 112 and the second thickness, t₂, or third thickness, t₃. Configuring the liquid metal droplets 112 in a monolayer can reduce the thermal resistance of the TIM layer 104.

In certain examples, the liquid metal droplets 112 may not be aligned in a monolayer as illustrated by liquid metal droplets 112a in FIG. 1. The amount of liquid metal droplets that span a thickness of the TIM layer 204′ can be configured by selecting the D₅₀ and/or D₉₀ of the liquid metal droplets 112a and the second thickness, t₂, or third thickness, t₃.

The TIM composition 204, including the first polymer component, can be cured to form the TIM layer 204′. Curing the TIM composition 204 can fix the liquid metal droplets 112 in the polymer component 110 in the second aspect ratio, inhibit pump out of the liquid metal droplets 112, and/or facilitate handling of the system 300, 500. Curing can occur during application of a force to the TIM composition 204, after application of the force to the TIM composition 204, or a combination thereof. In various examples, while the beginning of the curing process may occur before desired deformation of the liquid metal droplets 112, the completion of the curing process should occur after desired deformation of the liquid metal droplets 112.

As used in this specification, the terms “cure” and “curing” refer to the chemical cross-linking of components in an emulsion or material applied over a substrate, or the increase of viscosity of the components in the emulsion or material applied over the substrate. Accordingly, the terms “cure” and “curing” do not encompass solely physical drying of an emulsion or material through solvent or carrier evaporation. In this regard, the term “cured,” as used in this specification in examples comprising a thermosetting polymer, refers to the condition of an emulsion or material in which a component of the emulsion or material has chemically reacted to form new covalent bonds in the emulsion or material (e.g., new covalent bonds formed between a binder resin and a curing agent). The term “cured”, as used in this specification in examples comprising a thermoplastic polymer, refers to the condition of an emulsion or material in which the temperature of the thermoplastic polymer decreases below the melting point of the thermoplastic polymer such that the viscosity of the emulsion or material increases. In examples comprising both a thermosetting polymer and a thermoplastic polymer, the term “cured” refers to one of or both of the polymers curing as described herein.

Curing the TIM composition 204 can comprise at least one of heating the TIM composition 204 (e.g., in examples with a thermosetting polymer), adding a catalyst to the TIM composition 204 (e.g., platinum catalyst, moisture), exposing the TIM composition 204 to air, cooling the TIM composition 204 (e.g., in examples with a thermoplastic polymer), applying electromagnetic radiation (e.g., photo-polymerization), and applying pressure to the TIM composition 204. Curing the TIM composition 204 can increase the viscosity of the TIM composition 204. For example, the TIM layer 204′ can comprise a viscosity after curing that is at least double of the TIM composition 204 prior to curing, such as, for example, at least triple, at least quadrupole, or ten times a viscosity of the TIM composition 204 prior to curing. For example, the TIM layer 204′ can comprise a viscosity after curing of greater than 15,000 cP, such as, for example, greater than 20,000 cP, greater than 30,000 cP, greater than 50,000 cP, greater than 100,000 cP, greater than 150,000 cP, greater than 200,000 cP, greater than 250,000 cP, greater than 500,000 cP, greater than 750,000 cP, greater than 850,000 cP, greater than 1,000,000 cP, greater than 1,500,000 cP, greater than 2,500,000 cP, greater than 4,000,000 cP, or greater than 5,000,000 cP.

Before curing, the TIM composition 204 can comprise mechanical properties of a Bingham plastic and after curing the TIM layer 204′ can comprise mechanical properties of an elastic solid. For example, the TIM layer 204′ can be elastomeric and may have an ultimate tensile strain of at least 30%, such as, for example at least 50%, at least 100%, at least 200%, or at least 300%. Ultimate tensile strain can be measured according to ASTM D3039. In the uncured state, the TIM composition 204 can comprise a storage modulus (G′) greater than the loss modulus (G″) of the TIM composition 204 over relevant frequencies (e.g., less than 100 rad/s). In various examples, the TIM layer 204′ can behave more like a solid than a liquid.

In the cured state, the TIM layer 204′ can comprise a storage modulus (G′) in a range of 10⁴ Pa to 10⁷ Pa as measured according to ASTM D7175 using a parallel plate rheometer, such as, for example, 10⁴ Pa to 10⁶ Pa or 7×10⁴ Pa to 5×10⁷ Pa.

The cure time of the TIM composition 204 can be in a range of 1 minute to 48 hours, such as, for example, 1 minute to 24 hours, 1 minute to 12 hours, 1 minute to 1 hour, 2 minutes to 1 hour, 2 minutes to 30 minutes, 5 minutes to 1 hour, 10 minutes to 1 hour, 30 minutes to 2 hours, 1 minute to 10 minutes, or 1 hour to 2 hours.

Referring back to FIG. 1, each adhesive layer 130 and 132, can be the same or different. Each polymer component, individually, in the adhesive layers 130 and 132 can be configured as the polymer component described herein with respect to the polymer component in the TIM composition 204.

The polymer component in the adhesive layers 130 and 132 can be a partially uncured polymer component. For example, the partially uncured polymer component can comprise at least one of an acrylic polymer, an acrylate polymer, a vinyl polymer, a polyester polymer, a polyurethane polymer, a polybutadiene polymer, a polyamide polymer, a polyether polymer, a polysiloxane polymer, a silicon hydride polymer, a fluoropolymer, a polyisoprene polymer, and a copolymer of any two or more thereof. In various examples, the partially uncured polymer component and the first polymer component can comprise the same polymer. The polymer component in the adhesive layers 130 and 132 can be the same or different than the polymer component in the TIM layer 104. In certain examples, the partially uncured polymer component and the first polymer component can comprise different polymers.

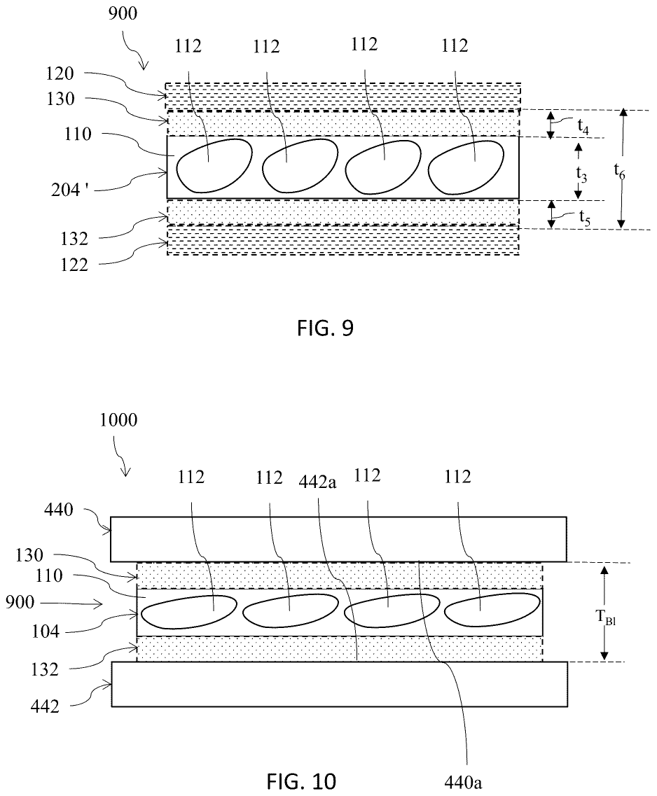

Referring to FIG. 5 and FIG. 9, the adhesive layer 130 can be applied (e.g., deposited) at a fourth thickness, t₄, on the TIM composition 204, the TIM layer 204′, or a combination thereof. The adhesive layer 132 can be applied (e.g., deposited) at a fifth thickness, t₅, on the TIM composition 204, the TIM layer 204′, or a combination thereof. For example, the adhesive layer 130 and/or the adhesive layer 132 can be applied prior to, during, and/or after curing of the TIM composition 204.

The adhesive layers 130 and 132 can be applied by, for example, at least one of dispensing (e.g., auger controlled, air controlled, time-pressure), extruding (e.g., through a nozzle, such as, a circular nozzle, a fan nozzle, or other nozzle shape), applying with a utensil (e.g., brush, spatula), stencil printing, 3D printing, screen printing, spin coating, calendaring, film casting, slot-die coating, roll-to-roll manufacturing, or a combination thereof. In various examples, the adhesive layers 130 and 132 can be applied directly to the TIM composition 204 and/or the TIM layer 204′. In various other examples, the adhesive layers 130 and 132 can be applied directly to the temporary substrate 120 and the temporary substrate 122, respectively and then can be applied directly to the TIM composition 204 and/or TIM layer 204′. In certain examples, the adhesive layers 130 and 132 can be applied to the temporary substrate 120 and/or the temporary substrate 122, and/or the TIM composition 204 and/or the TIM layer 204′.

The fourth thickness, t₄, and fifth thickness, t₅, can be selected to enhance the effective thermal conductivity of the system 500, 900 and enable a desired adhesion to a substrate. For example, the fourth thickness, t₄, and/or fifth thickness, t₅, individually can be in a range of 5 microns to 50 microns or 5 to 20 microns.

The adhesive layer 130 and/or adhesive layer 132 can be adhered to the TIM layer 204′. The adhesive layer 130 and/or adhesive layer 132 can be capable to adhere the system 100 to surfaces. The adhesive layer 130 and/or adhesive layer 132 can enhance the adhesive strength of the system 500, 900. The adhesive layer 130 and/or adhesive layer 132 can be capable to adhesively fail (e.g., delaminate; adhesive strength is less than the ultimate tensile strength), cohesively fail (e.g., layer rips; adhesive strength is greater than the ultimate tensile strength), partially adhesively fail and partially cohesively fail depending on the application. In examples where the adhesive layer 130 and/or adhesive layer 132 is capable of cohesive failure, the maximum interfacial adhesive stress of the adhesive layer 130 and/or adhesive layer 132 to the target substrate is greater than the maximum shear and/or tensile stress of the TIM layer 104.

For example, the adhesive layer 130 and/or adhesive layer 132 can exhibit an adhesive strength that is at least 5% greater than an adhesive strength of the TIM layer 204′ without the respective adhesive layer, such as, for example, at least 10% greater, at least 20% greater, at least 30% greater, at least 40% greater, or at least 50% greater than the TIM layer 204′ without the respective adhesive layer.

The adhesive layer 130 and/or adhesive layer 132 can exhibit an adhesive strength in a range of 10³ to 10⁸ Pa, such as, for example, 10⁵ to 10⁸ Pa. The adhesive strength can be measured using a universal testing machine following ASTM D897.

The adhesive layer 130 and/or adhesive layer 132 can exhibit an ultimate tensile strength of in a range of 10³ Pa and 10⁸ Pa, such as, for example, 10³ Pa to 10⁵ Pa, 10⁵ Pa to 10⁶ Pa, or 10⁶ Pa to 10⁸ Pa. Ultimate tensile strength can be measured according to ASTM D3039.

The adhesive layer 130 and/or adhesive layer 132 can comprise a storage modulus (G′) in a range of 10¹ Pa to 10⁵ Pa as measured using a parallel plate rheometer according to ASTM D7175, such as, for example, 10² Pa to 10⁵ Pa, 10³ Pa to 10⁵ Pa, or 10⁴ Pa to 10⁵ Pa.

The system 100, 300, 500, 700, 900 can comprise other layers and/or surface treatments. For example, a cure-inhibiting component can be applied to the temporary substrate 120 and/or temporary substrate 122 to enable release of the temporary substrate 120 and/or temporary substrate 122 prior to application of the system 100, 300, 500, 700, 900 to a surface in an assembly. For example, the cure-inhibiting component can comprise a desiccant, copper, a thiol, an amine, a chain stopper, sulfur, a solvent, or a combination thereof. In various non-limiting examples, the manufacture of the system 100, 300, 500, 700, 900 can be performed in an environment comprising a relative humidity of no greater than 40%.

The system 100, 300, 500, 700, 900 can comprise a sixth thickness, t₆. The sixth thickness, t₆, can be a total thickness of the system 100 excluding the temporary substrates 120 and 122. The sixth thickness, t₆, can be no greater than 2,000 microns, such as, for example, no greater than 1,900 microns, no greater than 1,500 microns, no greater than 1,000 microns, no greater than 500 microns, no greater than 250 microns, no greater than 200 microns, no greater than 150 microns, no greater than 145 microns, no greater than 140 microns, no greater than 125 microns, no greater than 100 microns, no greater than 80 microns, no greater than 70 microns, no greater than 50 microns, no greater than 40 microns, no greater than 35 microns, or no greater than 30 microns. The sixth thickness, t₆, can be at least 50 microns, such as, for example, at least 70 microns, at least 75 microns, at least 80 microns, at least 100 microns, at least 120 microns, at least 140 microns, at least 145 microns, at least 200 microns, at least 500 microns, or at least 1000 microns. The sixth thickness, t₆, can be in a range of 50 micron to 2,000 microns, such as, for example, 100 microns to 2,000 microns, 50 micron to 1,000 microns, 50 microns to 500 microns, 50 microns to 250 microns, 50 microns to 300 microns, 50 microns to 250 microns, 50 micron to 200 microns, or 50 microns to 150 microns. The thickness of the system 100 can be selected based on the desired application.

In various examples, the system 300, 500, 700, 900 can comprise various other layers. For example, a mold release layer can be present between TIM layer 204′ and temporary substrate 120 and/or between TIM layer 204′ and temporary substrate 122. In certain examples, a mold release layer can be present between adhesive layer 130 and temporary substrate 120 and/or between adhesive layer 132 and temporary substrate 122 another layer may be present in the

Referring to FIGS. 4 and 8, the system 300, 700 can be applied to an assembly 400 and 800 to facilitate heat transfer between components. Prior to applying the system 300, 700, the temporary substrates 120 and 122, if present, can be removed. The temporary substrates 120 and 122 can be removed by peeling and/or the TIM layer 204′ can be peeled off of the temporary substrates 120 and 122. In various examples, the temporary substrates 120 and 122 are removed immediately after manufacturing the system 300, 700.

The system 300, 700 can be applied in contact with and between a first component layer 440 and a second component layer 442 of the assembly 400, 800. For example, the TIM layer 204′ can be in direct contact with the first component layer 440 and the second component layer 442.

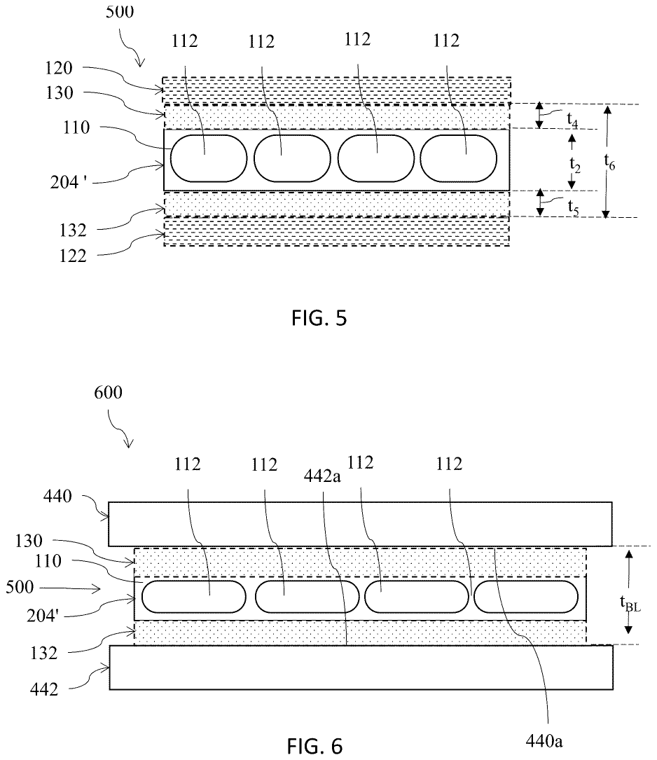

Referring to FIGS. 6 and 10, the system 500, 900 can optionally comprise adhesive layers 130 and 132. Prior to applying the system 500, 900, the temporary substrates 120 and 122, if present, can be removed. The temporary substrates 120 and 122 can be removed by peeling and/or the TIM layer 204′, adhesive layer 130, and adhesive layer 132 can be peeled off of the temporary substrates 120 and 122.

The system 500, 900 can be applied in contact with and between a first component layer 440 and a second component layer 442 of the assembly 600, 1000. For example, the adhesive layer 130 can be in direct contact with the first component layer 440 and the adhesive layer 132 can be in direct contact with the second component layer 442. The adhesive layers 130 and 132 can facilitate a bond between the first component layer 440 and the second component layer 442, and the system 100.

The system 100 comprising a cured TIM layer 204′ can facilitate handling of the system 100 and/or enhance manufacturability of assemblies. For example, the system 300, 500, 700, 900 can be handled by a pic and place robot.

After application of the system 300, 500, 700, 900, the assembly 400, 600, 800, 1000 can be compressed. For example, a force can be applied to the assembly to compress the system 300, 500, 700, 900 and further deform the liquid metal droplets 112. For example, a the first component layer 440 and the second component layer 442 can be move relative to the other to apply a force the TIM layer 204′. The force can be a normal force, which can be applied by urging the first component layer 440 and second component layer 442 together.

The force applied to the assembly 400, 600, 800, 1000 can be at least 3 kPa, such as, for example, at least 10 kPa, at least 70 kPa, at least 100 kPa, or at least 300 kPa. The force applied to the assembly 400, 600, 800, 1000 can be no greater than 2,000 kPa, such as, for example, no greater than 1,000 kPa, no greater than 600 kPa, no greater than 500 kPa, no greater than 300 kPa. For example, the force applied to the assembly 400, 600, 800, 1000 can be in a range of 3 kPa to 2,000 kPA, such as, for example, 3 kPa to 1,000 kPa, 3 kPa, to 600 kPa, 3 kPa to 100 kPa.

Applying a force to the assembly 400, 600, 800, 1000 can further deform the liquid metal droplets 112 dispersed within the polymer component 110 of the TIM layer 204′. Because the polymer component 110 is still elastomeric and conformable after curing, the force can deform the liquid metal droplets 112. In various examples, the liquid metal droplets 112 can be in the liquid phase during deformation, such that a lower pressure is required for the compression and a desired deformation can be achieved. The further deformation of the liquid metal droplets 112 can enhance thermal transfer in the system 300, 500, 700, 900.

In various examples, the liquid metal droplets 112 in the assembly 400, 600, 800, 1000 prior to application of the force can have a second average aspect ratio and after deformation the liquid metal droplets 112 can have a third average aspect ratio. The third average aspect ratio can be different than the second average aspect ratio. For example, the third average aspect ratio can be greater than the second average aspect ratio. In certain examples, the third aspect ratio can be at least 0.1 greater than the second aspect ratio, such as, for example, at least 0.5 greater than the second aspect ratio, at least 1 greater than the second aspect ratio, at least 2 greater than the second aspect ratio, or at least 5 greater than the second aspect ratio.

After compression, the bondline thickness, t_{Bl}, of the assembly 400, 600, 800, 1000 can be no greater than 2000 microns, such as, for example, no greater than 1900 microns, no greater than 1500 microns, no greater than 1000 microns, no greater than 500 microns, no greater than 300 microns, no greater than 250 microns, no greater than 200 microns, no greater than 150 microns, no greater than 145 microns, no greater than 140 microns, no greater than 125 microns, no greater than 100 microns, no greater than 80 microns, no greater than 70 microns, no greater than 50 microns, no greater than 40 microns, no greater than 35 microns, or no greater than 30 microns. The bondline thickness, t_{Bl}, of the assembly 400, 600, 800, 1000 can be at least 1 microns, such as, for example, at least 10 microns, at least 15 microns, at least 30 microns, at least 35 microns, at least 40 microns, at least 50 microns, at least 70 microns, at least 75 microns, at least 80 microns, at least 100 microns, at least 120 microns, at least 140 microns, at least 145 microns, or at least 200 microns. The bondline thickness, t_{BL}, of the assembly 400, 600, 800, 1000 can be in a range of 1 micron to 2000 microns, such as, for example, 1 micron to 1000 microns, 1 micron to 300 microns, 1 micron to 250 microns, 10 microns to 300 microns, 10 microns to 250 microns, 1 micron to 200 microns, 15 microns to 200 microns, 15 microns to 150 microns, 30 microns to 150 microns, 50 microns to 120 microns, 75 microns to 125 microns, or 15 microns to 100 microns.

The D₉₀ of the liquid metal droplets 112 in the TIM composition 204 prior to deformation (e.g., during manufacture of the TIM layer 204′ and during manufacture of the assembly 400, 600, 800, 1000) can be greater than the bondline thickness, t_{Bl}. For example, the D₉₀ of the liquid metal droplets 112 prior to deformation can be greater than the bondline thickness, t_{Bl}, such as, for example, 1% greater than the bondline thickness, t_{Bl}, 2% greater than the bondline thickness, t_{Bl}, 5% greater than the bondline thickness, t_{Bl}, 10% greater than the bondline thickness, t_{Bl}, 15% greater than the bondline thickness, t_{Bl}, 20% greater than the bondline thickness, t_{Bl}, 30% greater than the bondline thickness, t_{Bl}, 40% greater than the bondline thickness, t_{Bl}, 50% greater than the bondline thickness, t_{Bl}, or 75% greater than the bondline thickness, t_{Bl}. The D₉₀ of the liquid metal droplets 112 prior to deformation can be no more than 100% greater than the bondline thickness, t_{Bl}, such as, for example, no more than 75% greater than the bondline thickness, t_{Bl}, no more than 50% greater than the bondline thickness, t_{Bl}, no more than 40% greater than the bondline thickness, t_{Bl}, no more than 30% greater than the bondline thickness, t_{Bl}, no more than 20% greater than the bondline thickness, t_{Bl}, no more than 15% greater than the bondline thickness, t_{Bl}, no more than 10% greater than the bondline thickness, t_{Bl}, no more than 5% greater than the bondline thickness, t_{Bl}, or no more than 2% greater than the bondline thickness, t_{Bl}. The D₉₀ of the liquid metal droplets 112 in the TIM composition 204 prior to deformation can be equal to or less than the bondline thickness, t_{Bl}. For example, the D₉₀ of the liquid metal droplets 112 prior to deformation can be 1% or less than the bondline thickness, t_{Bl}, such as, for example, 2% or less than the bondline thickness, t_{Bl}, 3% or less than the bondline thickness, t_{Bl}, 5% or less than the bondline thickness, t_{Bl}, 10% or less than the bondline thickness, t_{Bl}, 15% or less than the bondline thickness, t_{Bl}, or 20% or less than the bondline thickness. The D₉₀ of the liquid metal droplets 112 prior to deformation can be in a range of 20% less than to 100% greater than the bondline thickness, t_{Bl}, such as, for example, 10% less than to 100% greater than the bondline thickness, t_{Bl}, 10% less than to 50% greater than the bondline thickness, t_{Bl}, 5% less than to 50% greater than the bondline thickness, t_{Bl}, 1% greater than to 100% greater than the bondline thickness, t_{Bl}, 1% greater than to 50% greater than the bondline thickness, t_{Bl}, 1% to 30% greater than the bondline thickness, t_{Bl}, 2% greater than to 30% greater than the bondline thickness, t_{Bl}, or 5% greater than to 20% greater than the bondline thickness, t_{Bl}. In certain examples, the D₉₀ of the liquid metal droplets 112 in the TIM composition 204 prior to deformation can be no greater than the bondline thickness, t_{Bl}.

In various examples, the relative liquid metal surface area coverage between the TIM layer 204′, and the first component layer 440 and the second component layer 442 can be increased by compression. For example, the relative liquid metal surface area coverage after compression can be in a range of 1% to 100%, such as, for example, 1% to 5%, 5% to 10%, 10% to 30%, 30% to 50%, or increasing until the liquid metal surface area coverage achieves 100%. As used herein, “relative liquid metal area coverage” is the surface area covered by the liquid metal normalized by the total contact surface area between the TIM layer 204′ and the first component layer 440 and second component layer 442. Relative liquid metal area coverage can be measured using cross-sectioning followed by optical imaging using a ZEISS Axio Zoom.V16 or confocal scanning acoustic microscopy using a Hitachi FineSAT III for CSAM.

The adhesive layers 130 and 132 of the system 500, 900 can be cured in the assembly 600, 1000. For example, the adhesive layers 130 and 132 can be capable to be cured by heating, moisture, drying, oxidation, pressure, catalyst, or a combination thereof. In various examples, exposing the adhesive layers 130 and 132 to air by removing the temporary substrates 120 and 122 can begin curing of the adhesive layers 130 and 132. Compressing the assembly 600, 1000 can begin curing process in examples where the adhesive layer 130 and/or 132 comprise a pressure sensitive adhesive.

In various examples, the assembly 400, 600, 800, 1000 can be heated. The heating of the assembly 400, 600, 800, 1000 can enhance adhesion of the system 300, 500, 700, 900 to the first component layer 440 and/or second component layer 442, cure the adhesive layers 130 and 132, and/or increase the storage modulus of the adhesive layers 130 and 132.

The D₅₀ and/or D₉₀ of the liquid metal droplets 112, deformation of the liquid metal droplets 112, and/or controlled compression of the TIM layer 204′ can improve the thermal resistance value of the system 300, 500, 700, 900. For example, the TIM layer 204′ can comprise a thermal resistance value of at least 0.5 (° K*mm²)/W, such as, for example, at least 1 (° K*mm²)/W, at least 2 (° K*mm²)/W, at least 3 (° K*mm²)/W, at least 5 (° K*mm²)/W, or at least 10 (° K*mm²)/W. The TIM layer 204′ can comprise a thermal resistance value of no greater than 30 (° K*mm²)/W, such as, for example, no greater than 20 (° K*mm²)/W, no greater than 15 (° K*mm²)/W no greater than 10 (° K*mm²)/W, no greater than 9 (° K*mm²)/W, no greater than 8 (° K*mm²)/W no greater than 7 (° K*mm²)/W, or no greater than 5 (° K*mm²)/W. The TIM layer 204′ can comprise a thermal resistance value in a range of 0.5 (° K*mm²)/W to 30 (° K*mm²)/W, such as, for example, 0.5 (° K*mm²)/W to 20 (° K*mm²)/W, 0.5 (° K*mm²)/W to 15 (° K*mm²)/W, 1 (° K*mm²)/W to 10 (° K*mm²)/W, 2 (° K*mm²)/W to 10 (° K*mm²)/W, or 2 (° K*mm²)/W to 8 (° K*mm²)/W. The thermal resistance value can be measured using a TIMA 5 instrument from NanoTest (Germany).

The D₅₀ and/or D₉₀ of the liquid metal droplets 112, deformation of the liquid metal droplets 112, and/or controlled compression of the TIM layer 204′ can improve the thermal conductivity value of the system 300, 500, 700, 900. For example, the TIM layer 204′ can comprise an effective thermal conductivity value of at least 0.5 W/m*K, such as, for example, at least 1 W/m*K, at least 5 W/m*K, at least 10 W/m*K, at least 12 W/m*K, at least 15 W/m*K, at least 17 W/m*K, or at least 20 W/m*K. The TIM layer 204′ can comprise an effective thermal conductivity value in a range of 0.5 W/m*K to 50 W/m*K, such as, for example, 1 W/m*K to 50 W/m*K, 5 W/m*K to 50 W/m*K, 10 W/m*K to 40 W/m*K or 10 W/m*K to 30 W/m*K. As used herein, the effective thermal conductivity is a thickness of the TIM divided by a thermal resistance of the TIM.

The first component layer 440 can be a heat-generating electronic component (e.g., a battery, memory, a data storage unit, a power inverter, a thermoelectric generator, a motor winding, an integrated circuit) and/or thermally connected to the heat-generating electronic component. The integrated circuit can comprise a processor (e.g., central processing unit (CPU), tensor processing unit (TPU), graphics processing unit (GPU), artificial intelligence focused processor, an ASIC, and/or a system-on-a-chip (SOC)). The second component layer 442 can be an upper layer that can be thermally conductive. The first component layer 440 and the second component layer 442, individually, can be at least one of a battery, a processor, a heat sink (e.g., fins, fan, liquid cooling, cold plate, heat sink, heat wick, heat pipe), an integrated heat spreader, a heat pipe, a case, a fan, a liquid cooler, a relay, a SiC power module, a GaN power module, a memory chip, an integrated circuit, an antenna, and packaging. In various examples, the first component layer 440 can comprise a processor and the second component layer 442 can comprise at least one of a heat sink, an integrated heat spreader, and packaging. In certain examples, the first component layer 440 can comprise an integrated heat spreader and the second component layer 442 can comprise at least one of a heat sink, an integrated heat spreader, and packaging. In various examples, the first component layer 440 can comprise a battery and the second component layer 442 can comprise at least one of a heat sink, an integrated heat spreader, and packaging.

The first component layer 440 and/or the second component layer 442 can be pretreated thereby forming a pretreated surface 440a and/or 442a, respectively. The pretreated surfaces 440a and 442a can be in contact with the system 300, 500, 700, 900. For example, referring to FIGS. 4 and 8, the pretreated surfaces 440a and 442a can be in direct contact with TIM layer 204′. Referring to FIGS. 6 and 9, the pretreated surface 440a can be in direct contact with adhesive layer 130 and the pretreated surface 442a can be in direct contact with adhesive layer 132.

The pretreated surfaces 440a and 442a can be produced by contacting a surface of the first component layer 440 and/or the second component layer 442 with ozone, a silane, a flux, a plasticizer, a solvent, or an adhesion promoter. For example, the pretreated surfaces 440a and 442a can be produced by treating a surface with ozone and then adding a coating to the surface by spraying, spin-coating, and/or dip-coating. In various examples, a plasticizer (e.g., toluene, short-chain polymer, can be deposited on the surface to form the pretreated surface. The plasticizer can soften the polymer component in the TIM layer 204′ thereby enabling conformability. The polymer component in the TIM layer 204′ may reharden by curing (e.g., evaporation of the plasticizer).

In various other examples, the system according to the present disclosure can be used in a system on a package. For example, a single horizontal TIM layer can be in contact with multiple dies on one side (e.g., the integrated circuit can comprise multiple dies, or multiple integrated circuits can be in contact with the same side of the TIM) and an upper layer or layers on a different side.

The system according to the present disclosure can be a film, such as, for example, a free standing film.

### EXAMPLES

The present disclosure will be more fully understood by reference to the following examples that provide illustrative non-limiting aspects of the invention. It is understood that the invention described in this specification is not necessarily limited to the examples described in this section.

LMEE (liquid metal embedded elastomer) films of various thicknesses and thermal conductivities were prepared from emulsions of liquid metal in two-part addition-cured silicones using drawdown and plate compression techniques. The film thicknesses ranged from 77 μm to 247 μm and the thermal conductivities ranged from 0.6 to 1.9 W/mK according to ASTM D5470.

LMEE films were prepared from emulsions of liquid metal in two-part addition-cured silicones. The pre-film emulsions can be prepared from neat polymers or can include liquid additives and rigid fillers. Liquid additives include curing inhibitors, wetting agents, dispersing agents, leveling agents, rheology modifiers, surface modifiers, defoamers, adhesion promoters, coupling agents, and processing modifiers familiar to those in the art. Rigid fillers may include thermal pigments, rheology modifiers, color pigments, extender pigments, and barrier fillers familiar to those in the art.

The general composition of the LMEE film used in the Examples is shown in Table 1.

TABLE 1
LMEE Film Composition

| Components | Percent by weight (% v/v) |
|---|---|
| Silicone binder | 5-95 |
| Liquid metal | 5-95 |
| Additives | 0.10-5.00 |
| Rigid fillers | 1.00-60.00 |

The following examples demonstrate the preparation of films from LMEE emulsions using drawdown or compression processing techniques. Example A is an LMEE-film based only on silicone binder and liquid metal. Examples B and C use dispersions of rigid fillers in polymers to form the LMEE film.

TABLE 2
Composition of Example A

| | | | Parts by |
|---|---|---|---|
| Component | Function | Material | weight (g) |
| 1 | Silicone binder | Vinylsilicone binder | 15.0 |
| 2 | Silicone binder | Silicone hydride binder | 15.0 |
| 3 | Liquid metal | Galinstan | 350.0 |
| | | Liquid metal loading (% v/v) | 64 |

For Example A, components 1-3 were added to planetary mixer cup and mixed to form homogeneous emulsion of liquid metal in silicone binder.

Example A film was prepared using a drawdown method and a plate compression method.

For the drawdown method, LMEE emulsion was transferred to glass plate lined with Teflon release paper and processed through drawdown bar gap of 100 μm and 250 μm. The processed films were then baked at 150 C for 1 h to form the final film.

For the plate compression method, LMEE emulsion was transferred to 25 mm diameter circular stainless steel plate lined with Teflon release paper. A top layer of Teflon release paper was added on top of the emulsion sample and a top stainless steel circular plate of 25 mm diameter was lowered to compress the sample to 80 μm and 250 μm. The compressed sample was heated at 120 C for 8 min to form the final film.

TABLE 3
Composition of Examples B and C

| | | | Parts by weight (g) | |
|---|---|---|---|---|
| | Function | Material | B | C |
| Part A | | | | |
| Component | | | | |
| 1 | Silicone binder | Vinylsilicone binder | 15.0 | 15.0 |
| 2 | Liquid additive | Polyether siloxane | — | 0.2 |
| 3 | Rigid filler | 20 um Aluminum Powder | — | 32.4 |
| 4 | Rigid filler | Graphene nanoplatelet | 2.7 | — |
| Part B | | | | |
| Component | | | | |
| 5 | Silicone binder | Silicone hydride | 25.0 | 25.0 |
| | | crosslinker | | |
| 6 | Liquid additive | Cure inhibitor | 0.3 | 0.3 |
| LMEE | | | | |
| Component | | | | |
| 8 | Rigid filler dispersion in | Part A | 17.7 | 47.6 |
| | silicone binder | | | |
| 9 | Inhibited crosslinker | Part B | 15.0 | 15.0 |
| 10 | Liquid metal | Galinstan | 190.2 | 257.8 |
| | | Liquid metal loading | 50.0 | 50.0 |
| | | (% v/v) | | |
| | | Liquid additive loading | 0.3 | 0.5 |
| | | (% v/v) | | |
| | | Rigid filler loading (% v/v) | 2.0 | 15 |

For Examples B and C, components 1-2 were mixed on planetary style mixer to sufficiently blend the binder and additives. Then, components 3-4 were dispersed in the resulting mixture. Components 5-6 were mixed separately to blend the binder and additives. Components 1-4 formed Part A of the LMEE emulsion. Components 5-6 formed Part B of the LMEE emulsion. Part B and liquid metal were added to Part A and mixed in planetary mixer to form the final LMEE emulsion.

Examples B and C films were prepared using a drawndown method and a plate compression method as described above.

### Thermal Characterization

Example films were evaluated for thermal conductivity according to ASTM D5470 using Nanotest TIMA5. Table 4 shows the measurement parameters used during the thermal conductivity testing.

TABLE 4
ASTM D5470 Measurement Parameters

| Parameter | Value |
|---|---|
| Test head material | Copper (uncoated) |
| Test head diameter (mm) | 13 |
| Heater temperature | 150 C. |
| Chiller temperature | 15 C. |
| TIM Temperature | 48 C. |
| Pressure (psi) | 30 |
| Compression rate (um/s) | 1 |

Examples A and C were measured at 250 um, while Example B was only measured at 80 um. Table 5 shows the results of the thermal characterization.

TABLE 5
Thermal Characterization Results

| | Bond-line | Thermal | Thermal |
|---|---|---|---|
| | thickness | resistance | Conductivity |
| Example | (um) | (mm2W/mK) | (W/mK) |
| A | 225 | 184 | 1.2 |
| B | 77 | 128 | 0.6 |
| C | 247 | 129 | 1.9 |

Those skilled in the art will recognize that the herein described compositions, articles, methods, and the discussion accompanying them are used as examples for the sake of conceptual clarity and that various configuration modifications are contemplated. Consequently, as used herein, the specific examples set forth and the accompanying discussion are intended to be representative of their more general classes. In general, use of any specific exemplar is intended to be representative of its class, and the non-inclusion of specific components (e.g., operations), devices, and objects should not be taken as limiting.

With respect to the appended claims, those skilled in the art will appreciate that recited operations therein may generally be performed in any order. Also, although various operational flows are presented in a sequence(s), it should be understood that the various operations may be performed in other orders than those that are illustrated or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

Although various examples have been described herein, many modifications, variations, substitutions, changes, and equivalents to those examples may be implemented and will occur to those skilled in the art. Also, where materials are disclosed for certain components, other materials may be used. It is therefore to be understood that the foregoing description and the appended claims are intended to cover all such modifications and variations as falling within the scope of the disclosed examples. The following claims are intended to cover all such modification and variations.

Various aspects of the invention according to the present disclosure include, but are not limited to, the aspects listed in the following numbered clauses.

Clause 1. A system comprising: a thermal interface material (TIM) layer comprising a first polymer component, and liquid metal droplets dispersed through the first polymer component, wherein the TIM layer exhibits a storage modulus of 10⁴ Pa to 10⁷ Pa; and a first adhesive layer disposed over the TIM layer.

Clause 2. The system of clause 1, wherein the liquid metal droplets comprise an aspect ratio of at least 1.1.

Clause 3. The system of clause 2, wherein a width of the liquid metal droplets are substantially aligned with a longitudinal plane of the TIM layer.

Clause 4. The system of clause 2, wherein a width of the liquid metal droplets are offset from a longitudinal plane of the TIM layer.

Clause 5. The system of any of clauses 1-4, wherein the first adhesive layer exhibits an adhesive strength that is at least 5% greater than an adhesive strength of the TIM layer without the first adhesive layer.

Clause 6. The system of any of clauses 1-5, wherein the first adhesive layer exhibits an adhesive strength in a range of 10³ to 10⁸ Pa.

Clause 7. The system of any of clauses 1-6, wherein the first adhesive layer exhibits an adhesive strength in a range of 10⁵ to 10⁸ Pa.

Clause 8. The system of any of clauses 1-7, wherein the first adhesive layer comprises a partially uncured polymer component with a storage modulus in a range of 10¹ to 10⁵ Pa.

Clause 9. The system of clause 8, wherein the partially uncured polymer component comprises at least one of an acrylic polymer, an acrylate polymer, a vinyl polymer, a polyester polymer, a polyurethane polymer, a polybutadiene polymer, a polyamide polymer, a polyether polymer, a polysiloxane polymer, a silicon hydride polymer, a fluoropolymer, a polyisoprene polymer, and a copolymer of any two or more thereof.

Clause 10. The system of any of clauses 8-9, wherein the partially uncured polymer component and the first polymer component comprise the same polymer.

Clause 11. The system of any of clauses 8-10, wherein the partially uncured polymer component and the first polymer component comprise different polymers.

Clause 12. The system of any of clauses 1-11, wherein the first adhesive layer is capable to be cured by heating, moisture, drying, oxidation, pressure, catalyst, or a combination thereof.

Clause 13. The system of any of clauses 1-12, further comprising: a second adhesive layer, wherein the TIM layer is positioned intermediate the first adhesive layer and the second adhesive layer.

Clause 14. The system of any of clauses 1-13, further comprising a first temporary substrate disposed in contact with the first adhesive layer.

Clause 15. The system of any of clauses 1-14, further comprising: a second adhesive layer, wherein the TIM layer is positioned intermediate the first adhesive layer and the second adhesive layer; a first temporary substrate disposed in contact with the first adhesive layer; and a second temporary substrate disposed in contact with the second adhesive layer.

Clause 16. The system of any of clauses 1-15, wherein the system comprises a thickness in a range of 50 microns to 2000 microns.

Clause 17. The system of any of clauses 1-16, wherein the first adhesive layer comprises a thickness in a range of 5 microns to 50 microns.

Clause 18. The system of any of clauses 1-17, wherein the TIM layer comprises a thickness in a range of 20 microns to 1990 microns.

Clause 19. The system of any of clauses 1-18, wherein the liquid metal droplets comprise at least one of gallium, a gallium alloy, indium, an indium alloy, tin, a tin alloy, mercury, and a mercury alloy.

Clause 20. The system of any of clauses 1-19, wherein the first polymer component comprises at least one of an acrylic polymer, an acrylate polymer, a vinyl polymer, a polyester polymer, a polyurethane polymer, a polybutadiene polymer, a polyamide polymer, a polyether polymer, a polysiloxane polymer, a silicon hydride polymer, a fluoropolymer, a polyisoprene polymer, and a copolymer of any two or more thereof.

Clause 21. The system of any of clauses 1-20, wherein the first polymer component is cured.

Clause 22. The system of any of clauses 1-21, wherein the liquid metal droplets comprise a D90 in a range of 1 micron to 300 microns.

Clause 23. The system of any of clauses 1-22, wherein a thickness of the TIM layer is in a range of 1 times to 1,000 times a D₉₀ of the liquid metal droplets.

Clause 24. The system of any of clauses 1-23, wherein a thickness of the TIM layer is in a range of 1 time to 1.25 times a D₉₀ of the liquid metal droplets.

Clause 25. The system of any of clauses 1-24, wherein a thickness of the TIM layer is in a range of 1.25 times to 3.3 times a D₉₀ of the liquid metal droplets.

Clause 26. The system of any of clauses 1-25, wherein a thickness of the TIM layer is in a range of 3.3 times to 10 times a D₉₀ of the liquid metal droplets.

Clause 27. The system of any of clauses 1-26, wherein a thickness of the TIM layer is in a range of 10 times to 100 times a D₉₀ of the liquid metal droplets.

Clause 28. The system of any of clauses 1-27, wherein a thickness of the TIM layer is in a range of 10 times to 100 times a D₉₀ of the liquid metal droplets.

Clause 29. The system of any of clauses 1-28, wherein the TIM layer further comprises at least one of a catalyst, rigid particles, deformable particles, a coupling agent, fumed silica, a conductive agent, an additive, and a surfactant.

Clause 30. The system of any of clauses 1-29, wherein the TIM layer has an ultimate tensile strain of at least 30%.

Clause 31. An assembly comprising: a first component layer; a second component layer; and the system of any of clauses 1-30 compressed and disposed in contact with and between the first component layer and the second component layer.

Clause 32. The assembly of clause 31, wherein a bondline thickness formed between the first component layer and the second component layer is no greater than 2000 microns.

Clause 33. The assembly of any of clauses 31-32, wherein the first component layer and the second component layer, individually, comprise at least one of a battery, a processor, a heat sink, an integrated heat spreader, a heat pipe, a case, a fan, a liquid cooler, a relay, a SiC power module, a GaN power module, a memory chip, an integrated circuit, an antenna and packaging.

Clause 34. The assembly of any of clauses 31-33, wherein the system comprises a thermal conductivity value of at least 0.5 W/m*K.

Clause 35. The assembly of any of clauses 31-34, wherein the first component layer, the second component layer, or a combination thereof, comprise a pretreated surface in contact with the system.

Clause 36. The assembly of clause 35, wherein the pretreated surface was produced by contacting a surface of the first component layer, the second component layer, or a combination thereof with ozone, a silane, a flux, a plasticizer, a solvent, or an adhesion promoter.

Clause 37. A method of manufacturing an assembly, the method comprising: applying the system of any of clauses 1-30 in contact with and between a first component layer of and a second component layer; and compressing the system.

Clause 38. The method of clause 37, further comprising heating the assembly.

Clause 39. A method comprising: applying a TIM composition to a temporary substrate at a first thickness, thereby forming a TIM layer, the TIM composition comprising a first polymer component, and liquid metal droplets dispersed through the first polymer component and having a first aspect ratio; applying a force to the TIM composition to deform the liquid metal droplets such that the liquid metal droplets have a second aspect ratio, wherein the second aspect ratio is greater than the first aspect ratio; and curing the first polymer component, thereby forming a TIM layer having the first polymer component that is cured and the liquid metal droplets having the second aspect ratio.

Clause 40. The method of clause 39, further comprising removing the temporary substrate.

Clause 41. The method of any of clauses 39-40, wherein applying a force to the TIM layer comprises applying a shear force to the TIM layer, such that a width of the liquid metal droplets are offset from a longitudinal plane of the TIM layer.

Clause 42. The method of any of clauses 39-41, wherein applying a force to the TIM layer comprises applying a normal force to the TIM layer to reduce the first thickness to a second thickness, such that a width of the liquid metal droplets are substantially aligned with a longitudinal plane of the TIM layer.

Clause 43. The method of any of clauses 39-42, wherein the first thickness is in a range of 30 microns to 500 microns.

Clause 44. The method of any of clauses 39-43, wherein curing the first polymer component occurs during applying a force to the TIM layer, after applying a force to the TIM layer, or a combination thereof.

Clause 45. The method of any of clauses 39-44, wherein applying the TIM composition to the temporary substrate comprises dispensing, extruding, applying with a utensil, stencil printing, 3d printing, screen printing, spin coating, calendaring, film casting, slot-die coating, or a combination thereof.

Clause 46. The method of any of clauses 39-45, further comprising applying an adhesive layer to the TIM composition, the TIM layer, or a combination thereof.

Clause 47. The method of any of clauses 39-46, further comprising a applying a cure-inhibiting component on the temporary substrate.

Clause 48. The method of clause 47, wherein the cure-inhibiting component comprises a desiccant, copper, a thiol, an amine, a chain stopper, sulfur, a solvent, or a combination thereof.

Clause 49. The method of any of clauses 39-48, wherein the method is performed in an environment comprising a relative humidity of no greater than 40%.

Clause 50. A method comprising: applying a thermal interface material (TIM) composition to a temporary substrate at a first thickness, thereby forming a TIM layer, the TIM composition comprising a first polymer component, and liquid metal droplets dispersed through the first polymer component and having a first aspect ratio; applying a force to the TIM layer to deform the liquid metal droplets such that the liquid metal droplets have a second aspect ratio, wherein the second aspect ratio is greater than the first aspect ratio; curing the first polymer component, thereby forming a cured layer having the first polymer component that is cured and the liquid metal droplets having the second aspect ratio; and applying an adhesive layer to the TIM layer, the cured layer, or a combination thereof.

Clause 51. The system of any one of clauses 1-30 produced by any of clauses 39-49.

Clause 52. The use of the system of any of clauses 1-30 as a thermal interface material.

Clause 53. A free standing film comprising: a thermal interface material (TIM) layer comprising a first polymer component, and liquid metal droplets dispersed through the first polymer component, wherein the TIM layer exhibits a storage modulus of 10⁴ Pa to 10⁷ Pa.

As used herein, “at least one of” a list of elements means one of the elements or any combination of two or more of the listed elements. As an example “at least of A, B, and C” means A only; B only; C only; A and B; A and C; B and C; or A, B, and C.

Various features and characteristics are described in this specification to provide an understanding of the composition, structure, production, function, and/or operation of the invention, which includes the disclosed compositions, TIMs, assemblies, and methods. It is understood that the various features and characteristics of the invention described in this specification can be combined in any suitable manner, regardless of whether such features and characteristics are expressly described in combination in this specification. The Inventors and the Applicant expressly intend such combinations of features and characteristics to be included within the scope of the invention described in this specification. As such, the claims can be amended to recite, in any combination, any features and characteristics expressly or inherently described in, or otherwise expressly or inherently supported by, this specification. Furthermore, the Applicant reserves the right to amend the claims to affirmatively disclaim features and characteristics that may be present in the prior art, even if those features and characteristics are not expressly described in this specification. Therefore, any such amendments will not add new matter to the specification or claims and will comply with the written description, sufficiency of description, and added matter requirements. The various non-limiting embodiments disclosed and described in this specification can comprise, consist of, or consist essentially of the features and characteristics as variously described herein.

Any numerical range recited in this specification describes all sub-ranges of the same numerical precision (i.e., having the same number of specified digits) subsumed within the recited range. For example, a recited range of “1.0 to 10.0” describes all sub-ranges between (and including) the recited minimum value of 1.0 and the recited maximum value of 10.0, such as, for example, “2.4 to 7.6,” even if the range of “2.4 to 7.6” is not expressly recited in the text of the specification. Accordingly, the Applicant reserves the right to amend this specification, including the claims, to expressly recite any sub-range of the same numerical precision subsumed within the ranges expressly recited in this specification. All such ranges are inherently described in this specification such that amending to expressly recite any such sub-ranges will comply with the written description, sufficiency of description, and added matter requirements.

Also, unless expressly specified or otherwise required by context, all numerical parameters described in this specification (such as those expressing values, ranges, amounts, percentages, and the like) may be read as if prefaced by the word “about,” even if the word “about” does not expressly appear before a number. Additionally, numerical parameters described in this specification should be construed in light of the number of reported significant digits, numerical precision, and by applying ordinary rounding techniques. It is also understood that numerical parameters described in this specification will necessarily possess the inherent variability characteristic of the underlying measurement techniques used to determine the numerical value of the parameters.

Notwithstanding that numerical ranges and parameters setting forth the broad scope of the invention are approximations, numerical values set forth in the specific examples are reported precisely as possible. Any numerical value, however, inherently contains certain errors necessarily resulting from the standard variation found in its respective testing measurements.

Reference throughout the specification to “various examples,” “some examples,” “one example,” “an example,” or the like means that a particular feature, structure, or characteristic described in connection with the example is included in an example. Thus, appearances of the phrases “in various examples,” “in some examples,” “in one example,” “in an example,” or the like, in places throughout the specification are not necessarily all referring to the same example. Furthermore, the particular features, structures, or characteristics may be combined in any suitable manner in an example or examples. Thus, the particular features, structures, or characteristics illustrated or described in connection with one example may be combined, in whole or in part, with the features, structures, or characteristics of another example or other examples without limitation. Such modifications and variations are intended to be included within the scope of the present examples.

Any patent, publication, or other document identified in this specification is incorporated by reference into this specification in its entirety unless otherwise indicated but only to the extent that the incorporated material does not conflict with existing descriptions, definitions, statements, illustrations, or other disclosure material expressly set forth in this specification. As such, and to the extent necessary, the express disclosure as set forth in this specification supersedes any conflicting material incorporated by reference. Any material, or portion thereof, that is incorporated by reference into this specification, but which conflicts with existing definitions, statements, or other disclosure material set forth herein, is only incorporated to the extent that no conflict arises between that incorporated material and the existing disclosure material. Applicant reserves the right to amend this specification to expressly recite any subject matter, or portion thereof, incorporated by reference. The amendment of this specification to add such incorporated subject matter will comply with the written description, sufficiency of description, and added matter requirements.

Whereas particular examples of this invention have been described above for purposes of illustration, it will be evident to those skilled in the art that numerous variations of the details of the present invention may be made without departing from the invention as defined in the appended claims.

While the present disclosure provides descriptions of various specific aspects for the purpose of illustrating various aspects of the present disclosure and/or its potential applications, it is understood that variations and modifications will occur to those skilled in the art. Accordingly, the invention or inventions described herein should be understood to be at least as broad as they are claimed and not as more narrowly defined by particular illustrative aspects provided herein.

It is understood that the inventions described in this specification are not limited to the examples summarized in the Summary or Detailed Description. Various other aspects are described and exemplified herein.

What is claimed is:

1. A system comprising:
a thermal interface material (TIM) layer comprising
a first polymer component, and
liquid metal droplets dispersed through the first polymer component,
wherein the TIM layer exhibits a storage modulus of 10⁴ Pa to 10⁷ Pa; and
a first adhesive layer disposed over the TIM layer.

2. The system of claim 1, wherein the liquid metal droplets comprise an aspect ratio of at least 1.1.

3. The system of claim 2, wherein a width of the liquid metal droplets are substantially aligned with a longitudinal plane of the TIM layer.

4. The system of claim 2, wherein a width of the liquid metal droplets are offset from a longitudinal plane of the TIM layer.

5. The system of claim 1, wherein the first adhesive layer exhibits an adhesive strength that is at least 5% greater than an adhesive strength of the TIM layer without the first adhesive layer.

6. The system of claim 1, wherein the first adhesive layer exhibits an adhesive strength in a range of 10³ to 10⁸ Pa.

7. The system of claim 1, wherein the first adhesive layer exhibits an adhesive strength in a range of 10⁵ to 10⁸ Pa.

8. The system of claim 1, wherein the first adhesive layer comprises a partially uncured polymer component with a storage modulus in a range of 10¹ to 10⁵ Pa.

9. The system of claim 8, wherein the partially uncured polymer component comprises at least one of an acrylic polymer, an acrylate polymer, a vinyl polymer, a polyester polymer, a polyurethane polymer, a polybutadiene polymer, a polyamide polymer, a polyether polymer, a polysiloxane polymer, a silicon hydride polymer, a fluoropolymer, a polyisoprene polymer, and a copolymer of any two or more thereof.

10. The system of claim 8, wherein the partially uncured polymer component and the first polymer component comprise the same polymer.

11. The system of claim 8, wherein the partially uncured polymer component and the first polymer component comprise different polymers.

12. The system of claim 1, wherein the first adhesive layer is capable to be cured by heating, moisture, drying, oxidation, pressure, catalyst, or a combination thereof.

13. The system of claim 1, further comprising:
a second adhesive layer, wherein the TIM layer is positioned intermediate the first adhesive layer and the second adhesive layer.

14. The system of claim 1, further comprising a first temporary substrate disposed in contact with the first adhesive layer.

15. The system of claim 1, further comprising:
a second adhesive layer, wherein the TIM layer is positioned intermediate the first adhesive layer and the second adhesive layer;
a first temporary substrate disposed in contact with the first adhesive layer; and
a second temporary substrate disposed in contact with the second adhesive layer.

16. The system of claim 1, wherein the system comprises a thickness in a range of 50 microns to 2000 microns.

17. The system of claim 1, wherein the first adhesive layer comprises a thickness in a range of 5 microns to 50 microns.

18. The system of claim 1, wherein the TIM layer comprises a thickness in a range of 20 microns to 1990 microns.

19. The system of claim 1, wherein the liquid metal droplets comprise at least one of gallium, a gallium alloy, indium, an indium alloy, tin, a tin alloy, mercury, and a mercury alloy.

20. The system of claim 1, wherein the first polymer component comprises at least one of an acrylic polymer, an acrylate polymer, a vinyl polymer, a polyester polymer, a polyurethane polymer, a polybutadiene polymer, a polyamide polymer, a polyether polymer, a polysiloxane polymer, a silicon hydride polymer, a fluoropolymer, a polyisoprene polymer, and a copolymer of any two or more thereof.

21. The system of claim 1, wherein the first polymer component is cured.

22. The system of claim 1, wherein the liquid metal droplets comprise a D₉₀ in a range of 1 micron to 300 microns.

23. The system of claim 1, wherein a thickness of the TIM layer is in a range of 1 times to 1,000 times a D₉₀ of the liquid metal droplets.

24. The system of claim 1, wherein a thickness of the TIM layer is in a range of 1 time to 1.25 times a D₉₀ of the liquid metal droplets.

25. The system of claim 1, wherein a thickness of the TIM layer is in a range of 1.25 times to 3.3 times a D₉₀ of the liquid metal droplets.

26. The system of claim 1, wherein a thickness of the TIM layer is in a range of 3.3 times to 10 times a D₉₀ of the liquid metal droplets.

27. The system of claim 1, wherein a thickness of the TIM layer is in a range of 10 times to 100 times a D₉₀ of the liquid metal droplets.

28. The system of claim 1, wherein a thickness of the TIM layer is in a range of 10 times to 100 times a D₉₀ of the liquid metal droplets.

29. The system of claim 1, wherein the TIM layer further comprises at least one of a catalyst, rigid particles, deformable particles, a coupling agent, fumed silica, a conductive agent, an additive, and a surfactant.

30. The system of claim 1, wherein the TIM layer has an ultimate tensile strain of at least 30%.

31. An assembly comprising:
a first component layer;
a second component layer; and
the system of claim 1 compressed and disposed in contact with and between the first component layer and the second component layer.

32. The assembly of claim 31, wherein a bondline thickness formed between the first component layer and the second component layer is no greater than 2000 microns.

33. The assembly of claim 31, wherein the first component layer and the second component layer, individually, comprise at least one of a battery, a processor, a heat sink, an integrated heat spreader, a heat pipe, a case, a fan, a liquid cooler, a relay, a SiC power module, a GaN power module, a memory chip, an integrated circuit, an antenna and packaging.

34. The assembly of claim 31, wherein the system comprises a thermal conductivity value of at least 0.5 W/m*K.

35. The assembly of claim 31, wherein the first component layer, the second component layer, or a combination thereof, comprise a pretreated surface in contact with the system.

36. The assembly of claim 35, wherein the pretreated surface was produced by contacting a surface of the first component layer, the second component layer, or a combination thereof with ozone, a silane, a flux, a plasticizer, a solvent, or an adhesion promoter.

37. A method of manufacturing an assembly, the method comprising:
applying the system of claim 1 in contact with and between a first component layer of and a second component layer; and
compressing the system.

38. The method of claim 37, further comprising heating the assembly.

39. A method comprising:
applying a TIM composition to a temporary substrate at a first thickness, thereby forming a TIM layer, the TIM composition comprising
a first polymer component, and
liquid metal droplets dispersed through the first polymer component and having a first aspect ratio;
applying a force to the TIM composition to deform the liquid metal droplets such that the liquid metal droplets have a second aspect ratio, wherein the second aspect ratio is greater than the first aspect ratio; and
curing the first polymer component, thereby forming a TIM layer having the first polymer component that is cured and the liquid metal droplets having the second aspect ratio.

40. The method of claim 39, further comprising removing the temporary substrate.

41. The method of claim 39, wherein applying a force to the TIM layer comprises applying a shear force to the TIM layer, such that a width of the liquid metal droplets are offset from a longitudinal plane of the TIM layer.

42. The method of claim 39, wherein applying a force to the TIM layer comprises applying a normal force to the TIM layer to reduce the first thickness to a second thickness, such that a width of the liquid metal droplets are substantially aligned with a longitudinal plane of the TIM layer.

43. The method of claim 39, wherein the first thickness is in a range of 30 microns to 500 microns.

44. The method of claim 39, wherein curing the first polymer component occurs during applying a force to the TIM layer, after applying a force to the TIM layer, or a combination thereof.

45. The method of claim 39, wherein applying the TIM composition to the temporary substrate comprises dispensing, extruding, applying with a utensil, stencil printing, 3d printing, screen printing, spin coating, calendaring, film casting, slot-die coating, or a combination thereof.

46. The method of claim 39, further comprising applying an adhesive layer to the TIM composition, the TIM layer, or a combination thereof.

47. The method of claim 39, further comprising a applying a cure-inhibiting component on the temporary substrate.

48. The method of claim 47, wherein the cure-inhibiting component comprises a desiccant, copper, a thiol, an amine, a chain stopper, sulfur, a solvent, or a combination thereof.

49. The method of claim 39, wherein the method is performed in an environment comprising a relative humidity of no greater than 40%.

50. A method comprising:
applying a thermal interface material (TIM) composition to a temporary substrate at a first thickness, thereby forming a TIM layer, the TIM composition comprising
a first polymer component, and
liquid metal droplets dispersed through the first polymer component and having a first aspect ratio;
applying a force to the TIM layer to deform the liquid metal droplets such that the liquid metal droplets have a second aspect ratio, wherein the second aspect ratio is greater than the first aspect ratio;
curing the first polymer component, thereby forming a cured layer having the first polymer component that is cured and the liquid metal droplets having the second aspect ratio; and
applying an adhesive layer to the TIM layer, the cured layer, or a combination thereof.

51. A free standing film comprising:
a thermal interface material (TIM) layer comprising
a first polymer component, and
liquid metal droplets dispersed through the first polymer component,
wherein the TIM layer exhibits a storage modulus of 10⁴ Pa to 10⁷ Pa.
